(19) United States
(12) Patent Application Publication
(10) Pub. No.: US 2026/0233249 A1
(43) Pub. Date: Aug. 13, 2026

(54) SUBSTRATE TREATING METHOD AND SUBSTRATE TREATING APPARATUS, AND METHOD FOR MANUFACTURING SEMICONDUCTOR APPARATUS AND SEMICONDUCTOR MANUFACTURING APPARATUS

(71) Applicant: SCREEN Holdings Co., Ltd., Kyoto (JP)

(72) Inventors: Yusuke UEDA, Kyoto (JP); Yukifumi YOSHIDA, Kyoto (JP); Yasuharu MIYAMOTO, Kyoto (JP)

(21) Appl. No.: 19/151,813

(22) PCT Filed: Dec. 13, 2023
(86) PCT No.: PCT/JP2023/044687

§ 371 Date: Jul. 29, 2025

(30) Foreign Application Priority Data
Mar. 22, 2023 (JP) 2023-046049

(51) Int. Cl. B05C 3/05; B05C 3/09; H10P 50/00

(52) U.S. Cl. CPC B05C 3/05; B05C 3/09; H10P 50/73

(57) ABSTRACT

A substrate treating method of the present invention includes a dispersion liquid generation step of generating a dispersion liquid in which water is uniformly dispersed in an organic solvent as a main solvent, a treating liquid generation step of adding a SAM forming material to the dispersion liquid to generate a treating liquid containing SAM molecules, and a layer forming step of bringing the treating liquid into contact with the surface to chemically adsorb the SAM molecules and form the SAM, in which the dispersion liquid generation step is a step of mixing the organic solvent and the water while applying an ultrasonic wave or of mixing the organic solvent and the water and then applying an ultrasonic wave to generate the dispersion liquid, and the treating liquid generation step is a step of generating the treating liquid without applying an ultrasonic wave.

### TECHNICAL FIELD

The present invention relates to a substrate treating method and a substrate treating apparatus capable of efficiently forming a self-assembled monolayer excellent in denseness and protection performance in a short time, a method of manufacturing a semiconductor apparatus, and a semiconductor manufacturing apparatus.

### BACKGROUND ART

In the manufacture of a semiconductor apparatus, a photolithography technique is widely used as a technique of selectively forming a layer in a specific surface region of a substrate. For example, an insulating film is formed after a lower layer wiring is formed, a dual damascene structure having a trench and a via hole is formed by photolithography and etching, and a conductive film of Cu or the like is embedded in the trench and the via hole to form a wiring.

However, in recent years, miniaturization of semiconductor apparatus has progressed more and more, and alignment accuracy is not sufficient in a photolithography technique in some cases. For this reason, instead of the photolithography technique, a technique of selectively forming a film with high accuracy in a specific region on the surface of the substrate is required.

For example, Patent Document 1 discloses a method in which, in order to selectively etch a silicon nitride film in a substrate provided with a silicon nitride (SiN) film and a silicon oxide (SiO₂) film in a plane, a thermal phosphoric acid-resistant material is formed in advance as a SAM on a surface of the silicon oxide film.

Here, in order to sufficiently protect the silicon oxide film from an etching liquid, it is necessary to form a SAM excellent in denseness. However, a conventional method of forming a SAM has a problem that it is difficult to form such a SAM excellent in denseness in a short time, and the production efficiency is poor.

### PRIOR ART DOCUMENT

### Patent Document

Patent Document 1: JP 5490071 B2

### SUMMARY OF THE INVENTION

### Problems to be Solved by the Invention

The present invention has been made in view of the above problems, and an object of the present invention is to provide a substrate treating method and a substrate treating apparatus capable of efficiently forming a self-assembled monolayer excellent in denseness and protection performance on a surface of a substrate in a short time, a method for manufacturing a semiconductor apparatus, and a semiconductor manufacturing apparatus by suppressing or reducing occurrence of layer defects.

### Solutions to the Problems

In order to solve the above problem, a substrate treating method according to the present invention is a substrate treating method for forming a self-assembled monolayer on a surface of a substrate, the substrate treating method comprising a dispersion liquid generation step of generating a dispersion liquid in which water is uniformly dispersed in an organic solvent as a main solvent, a treating liquid generation step of adding a material containing a molecule that has a functional group exhibiting hydrolysis reactivity and allows formation of the self-assembled monolayer to the dispersion liquid, and causing a hydrolysis reaction of the water dispersed in the dispersion liquid and the functional group to generate a treating liquid containing the molecule having a hydroxyl group and in which the molecule having a hydroxyl group exists without being aggregated and a layer forming step of forming the self-assembled monolayer by supplying the treating liquid to the surface of the substrate, wherein the dispersion liquid generation step is a step of mixing the organic solvent and the water while applying an ultrasonic wave or of mixing the organic solvent and the water and then applying an ultrasonic wave to generate the dispersion liquid, and the treating liquid generation step is a step performed in a state where no ultrasonic wave is applied to the dispersion liquid.

In the above configuration, a dispersion liquid generation step includes generating a dispersion liquid by mixing an organic solvent and water while applying an ultrasonic wave, or mixing the organic solvent and the water and then applying an ultrasonic wave. In this manner, in the dispersion liquid generation step, the dispersion liquid in which the water is uniformly dispersed in the organic solvent as a main solvent can be obtained. Furthermore, in the treating liquid generation step, a material (hereinafter referred to as “SAM forming material”) containing a molecule (hereinafter referred to as “SAM molecule”) capable of forming a self-assembled monolayer (hereinafter referred to as “SAM”) is added to the dispersion liquid obtained in the dispersion liquid generation step without applying an ultrasonic wave to generate a treating liquid. Here, the SAM molecule has a functional group exhibiting hydrolysis reactivity, and water molecules are uniformly dispersed in the dispersion liquid. Therefore, when the SAM forming material is added to the dispersion liquid, the functional group exhibiting hydrolysis reactivity in the SAM molecules undergoes a hydrolysis reaction with the water molecules in the dispersion liquid to become a hydroxyl group (OH group). In this manner, a treating liquid containing a SAM molecule having a hydroxyl group can be produced. In the treating liquid generation step, the treating liquid is generated such that SAM molecules having hydroxyl groups exist without being aggregated with each other. In the treating liquid generation step, by generating the treating liquid without applying ultrasonic waves, the treating liquid can be generated such that SAM molecules having hydroxyl groups exist without being aggregated with each other. By generating the treating liquid such that the SAM molecules having the hydroxyl groups exist without being aggregated with each other, a self-assembled monolayer can be favorably formed in the layer forming step.

Furthermore, in the layer forming step, by bringing the treating liquid into contact with the surface of the substrate, a dehydration condensation reaction occurs between the hydroxyl group of the SAM molecule and the hydroxyl group existing on the surface of the substrate, and the SAM molecule can be chemically adsorbed. The chemically adsorbed SAM molecules further self-assemble to form a SAM.

As described above, in the above configuration, the hydroxyl group is introduced into the SAM molecules to be chemically adsorbed on the surface of the substrate by a hydrolysis reaction in advance at a generation stage of the treating liquid. Therefore, as compared with a case where the SAM is formed by using the SAM molecule to which the hydroxyl group is not introduced, the hydrolysis reaction of the SAM molecule, which is a rate-limiting step in a formation process of the SAM, can be omitted. Since the treating liquid contains the SAM molecules having hydroxyl groups without being aggregated, a dehydration condensation reaction between the SAM molecules having hydroxyl groups and the hydroxyl groups on the surface of the substrate also effectively occurs, the reaction being the rate-limiting step in the formation process of the SAM. Therefore, the SAM molecules can be chemically adsorbed on the surface of the substrate at high density. In this manner, in the above configuration, it is possible to suppress the occurrence of layer defects and efficiently form a SAM excellent in denseness and protection performance in a short time without bringing the SAM molecules into contact with the surface of the substrate for a long time in order to form a compact SAM as in a conventional substrate treating method.

According to the above configuration, an addition amount of the water in the dispersion liquid generation step is preferably in a range of 50 ppm or more and 200 ppm or less in the dispersion liquid.

By setting the addition amount of water to 50 ppm or more, it is possible to prevent the hydrolysis reaction of the functional group exhibiting hydrolysis reactivity in the SAM molecule from becoming insufficient, and it is possible to allow a sufficient amount of the SAM molecule into which the hydroxyl group is introduced to exist in the treating liquid. As a result, it is possible to suppress the occurrence of layer defects and form a SAM excellent in denseness without bringing SAM molecules into contact with the surface of the substrate for a long time in order to form a compact SAM as in the conventional substrate treating method. On the other hand, by setting the addition amount of water to 200 ppm or less, it is possible to suppress excessive aggregation of SAM molecules having a hydroxyl group due to a dehydration condensation reaction. As a result, it is possible to suppress a decrease in density of the SAM molecules to be chemically adsorbed on the surface of the substrate and to form a SAM excellent in denseness.

According to the above configuration, it is preferable that, in the treating liquid generation step, the material containing the molecule that allows formation of the self-assembled monolayer is added to the dispersion liquid left still.

When the SAM forming material is added to the dispersion liquid, in a case where the addition is performed while a mechanical force such as stirring and shaking is applied to the dispersion liquid, the SAM molecules having the hydroxyl groups may be aggregated with each other. However, by adding the SAM forming material to the dispersion liquid in a state of being still to adjust the treating liquid as in the above configuration, it is possible to further suppress the aggregation of the SAM molecules having the hydroxyl groups with each other and to generate the treating liquid.

In order to solve the above problem, a method for manufacturing a semiconductor apparatus according to the present invention is a method for manufacturing a semiconductor apparatus including a treatment of a substrate in which a stacked body is provided on a surface, the stacked body including layers in which a layer to be protected that is to be protected from etching and a layer to be etched that is to be etched are alternately stacked, the method for manufacturing the semiconductor apparatus comprising a step of selectively forming a self-assembled monolayer on at least a surface of the layer to be protected and a step of selectively etching the layer to be etched by using the self-assembled monolayer as a protective layer, wherein the step of forming a self-assembled monolayer includes a dispersion liquid generation step of generating a dispersion liquid in which water is uniformly dispersed in an organic solvent as a main solvent, a treating liquid generation step of adding a material containing a molecule that has a functional group exhibiting hydrolysis reactivity and allows formation of the self-assembled monolayer to the dispersion liquid, and causing a hydrolysis reaction of the water dispersed in the dispersion liquid and the functional group to generate a treating liquid containing the molecule having a hydroxyl group and in which the molecule having the hydroxyl group exists without being aggregated, and a layer forming step of forming the self-assembled monolayer by supplying the treating liquid to the surface of the substrate, and the dispersion liquid generation step is a step of mixing the organic solvent and the water while applying an ultrasonic wave or of mixing the organic solvent and the water and then applying an ultrasonic wave to generate the dispersion liquid, and the treating liquid generation step is a step performed in a state where no ultrasonic wave is applied to the dispersion liquid.

In the above configuration, a dispersion liquid generation step includes generating a dispersion liquid by mixing an organic solvent and water while applying an ultrasonic wave, or mixing the organic solvent and the water and then applying an ultrasonic wave. In this manner, in the dispersion liquid generation step, the dispersion liquid in which the water is uniformly dispersed in the organic solvent as a main solvent can be obtained. Furthermore, in the treating liquid generation step, the SAM forming material containing the SAM molecules is added to the dispersion liquid obtained in the dispersion liquid generation step without applying an ultrasonic wave to generate a treating liquid. Here, the SAM molecule has a functional group exhibiting hydrolysis reactivity, and water molecules are uniformly dispersed in the dispersion liquid. Therefore, when the SAM forming material is added to the dispersion liquid, the functional group exhibiting hydrolysis reactivity in the SAM molecules undergoes a hydrolysis reaction with the water molecules in the dispersion liquid to become a hydroxyl group (OH group). In this manner, a treating liquid containing a SAM molecule having a hydroxyl group can be produced. In the treating liquid generation step, the treating liquid is generated such that SAM molecules having hydroxyl groups exist without being aggregated with each other. In the treating liquid generation step, by generating the treating liquid without applying ultrasonic waves, the treating liquid can be generated such that SAM molecules having hydroxyl groups exist without being aggregated with each other. By generating the treating liquid such that the SAM molecules having the hydroxyl groups exist without being aggregated with each other, a self-assembled monolayer can be favorably formed in the layer forming step.

Furthermore, in the layer forming step, by bringing the treating liquid into contact with the surface of the substrate, a dehydration condensation reaction occurs between the hydroxyl group of the SAM molecule and the hydroxyl group existing on the surface of the substrate, and the SAM molecule can be chemically adsorbed. The chemically adsorbed SAM molecules further self-assemble to form a SAM.

As described above, in the above configuration, the hydroxyl group is introduced into the SAM molecules to be chemically adsorbed on the surface of the substrate by a hydrolysis reaction in advance at a generation stage of the treating liquid. Therefore, as compared with a case where the SAM is formed by using the SAM molecule to which the hydroxyl group is not introduced, the hydrolysis reaction of the SAM molecule, which is a rate-limiting step in a formation process of the SAM, can be omitted. Since the treating liquid contains the SAM molecules having hydroxyl groups without being aggregated, a dehydration condensation reaction between the SAM molecules having hydroxyl groups and the hydroxyl groups on the surface of the substrate also effectively occurs, the reaction being the rate-limiting step in the formation process of the SAM. Therefore, the SAM molecules can be chemically adsorbed on the surface of the substrate at high density. In this manner, in the above configuration, it is possible to suppress the occurrence of layer defects and efficiently form a SAM excellent in denseness and protection performance in a short time without bringing the SAM molecules into contact with the surface of the substrate for a long time in order to form a compact SAM as in a conventional method for manufacturing a semiconductor apparatus.

According to the above configuration, an addition amount of the water in the dispersion liquid generation step is preferably in a range of 50 ppm or more and 200 ppm or less in the dispersion liquid.

By setting the addition amount of water to 50 ppm or more, it is possible to prevent the hydrolysis reaction of the functional group exhibiting hydrolysis reactivity in the SAM molecule from becoming insufficient, and it is possible to allow a sufficient amount of the SAM molecule into which the hydroxyl group is introduced to exist in the treating liquid. As a result, it is possible to suppress the occurrence of layer defects and form a SAM excellent in denseness without bringing SAM molecules into contact with the surface of the substrate for a long time in order to form a compact SAM as in the conventional method for manufacturing a semiconductor apparatus. On the other hand, by setting the addition amount of water to 200 ppm or less, it is possible to suppress excessive aggregation of SAM molecules having a hydroxyl group due to a dehydration condensation reaction. As a result, it is possible to suppress a decrease in density of the SAM molecules to be chemically adsorbed on the surface of the substrate and to form a SAM excellent in denseness.

According to the above configuration, it is preferable that, in the treating liquid generation step, the material containing the molecule that allows formation of the self-assembled monolayer is added to the dispersion liquid left still.

When the SAM forming material is added to the dispersion liquid, in a case where the addition is performed while a mechanical force such as stirring and shaking is applied to the dispersion liquid, the SAM molecules having the hydroxyl groups may be aggregated with each other. However, by adding the SAM forming material to the dispersion liquid in a state of being still to adjust the treating liquid as in the above configuration, it is possible to further suppress the aggregation of the SAM molecules having the hydroxyl groups with each other and to generate the treating liquid.

In order to solve the above problem, a substrate treating apparatus according to the present invention is a substrate treating apparatus that forms a self-assembled monolayer on a surface of a substrate, the substrate treating apparatus comprising a treating liquid generation portion that generates a treating liquid containing a molecule that allows formation of the self-assembled monolayer, an ultrasonic wave application portion and a treating liquid supply portion that supplies the treating liquid generated by the treating liquid generation portion to the surface of the substrate to form the self-assembled monolayer, wherein the treating liquid generation portion generates a dispersion liquid in which water is uniformly dispersed in an organic solvent as a main solvent, further adds a material containing a molecule that allows formation of the self-assembled monolayer to the dispersion liquid, and causes a hydrolysis reaction of the water dispersed in the dispersion liquid and the functional group to generate the treating liquid containing the molecule having a hydroxyl group and in which the molecule having the hydroxyl group exists without being aggregated, and the ultrasonic wave application portion applies an ultrasonic wave when or after the organic solvent and the water are mixed in the treating liquid generation portion to generate the dispersion liquid.

In the above configuration, the treating liquid generation portion mixes the organic solvent as the main solvent with water to generate a mixed liquid. Then, the ultrasonic wave application portion applies an ultrasonic wave when the treating liquid generation portion mixes the organic solvent with the water or applies an ultrasonic wave to a mixed liquid generated by mixing the organic solvent with the water. In this manner, the treating liquid generation portion can generate the dispersion liquid in which the water is uniformly dispersed in the organic solvent. Furthermore, the treating liquid generation portion adds the material SAM forming material containing the SAM molecules to the generated dispersion liquid without applying an ultrasonic wave to generate the treating liquid. Here, the SAM molecule has a functional group exhibiting hydrolysis reactivity, and water molecules are uniformly dispersed in the dispersion liquid. Therefore, when the SAM forming material is added to the dispersion liquid, the functional group exhibiting hydrolysis reactivity in the SAM molecules undergoes a hydrolysis reaction with the water molecules in the dispersion liquid to become a hydroxyl group (OH group). In this manner, a treating liquid containing a SAM molecule having a hydroxyl group can be produced. The treating liquid generation portion generates the treating liquid such that SAM molecules having hydroxyl groups exist without being aggregated with each other. By generating the treating liquid without applying ultrasonic waves, the treating liquid generation portion can generate the treating liquid such that SAM molecules having hydroxyl groups exist without being aggregated with each other. By generating the treating liquid such that the SAM molecules having the hydroxyl groups exist without being aggregated with each other, a self-assembled monolayer can be favorably formed on the surface of the substrate.

Furthermore, the treating liquid supply portion supplies the treating liquid to the surface of the substrate to bring the SAM molecules into contact with the surface of the substrate, and causes a dehydration condensation reaction between the hydroxyl group of the SAM molecules and the hydroxyl group existing on the surface of the substrate. As a result, the SAM molecules can be chemically adsorbed on the surface of the substrate, and the chemically adsorbed SAM molecules can be self-assembled to form a SAM.

As described above, in the above configuration, the hydroxyl group is introduced into the SAM molecules to be chemically adsorbed on the surface of the substrate by a hydrolysis reaction in advance at a generation stage of the treating liquid. Therefore, as compared with a case where the SAM is formed by using the SAM molecule to which the hydroxyl group is not introduced, the hydrolysis reaction of the SAM molecule, which is a rate-limiting step in a formation process of the SAM, can be omitted. Since the treating liquid contains the SAM molecules having hydroxyl groups without being aggregated, a dehydration condensation reaction between the SAM molecules having hydroxyl groups and the hydroxyl groups on the surface of the substrate also effectively occurs, the reaction being the rate-limiting step in the formation process of the SAM. Therefore, the SAM molecules can be chemically adsorbed on the surface of the substrate at high density. In this manner, in the above configuration, it is possible to suppress the occurrence of layer defects and efficiently form a SAM excellent in denseness and protection performance in a short time without bringing the SAM molecules into contact with the surface of the substrate for a long time in order to form a compact SAM as in a conventional substrate treating apparatus.

According to the above configuration, an addition amount of the water when the organic solvent and the water are mixed in the treating liquid generation portion is preferably in a range of 50 ppm or more and 200 ppm or less.

By setting the addition amount of water to 50 ppm or more, it is possible to prevent the hydrolysis reaction of the functional group exhibiting hydrolysis reactivity in the SAM molecule from becoming insufficient, and it is possible to allow a sufficient amount of the SAM molecule into which the hydroxyl group is introduced to exist in the treating liquid. As a result, it is possible to suppress the occurrence of layer defects and form a SAM excellent in denseness without bringing SAM molecules into contact with the surface of the substrate for a long time in order to form a compact SAM as in the conventional substrate treating apparatus. On the other hand, by setting the addition amount of water to 200 ppm or less, it is possible to suppress excessive aggregation of SAM molecules having a hydroxyl group due to a dehydration condensation reaction. As a result, it is possible to suppress a decrease in density of the SAM molecules to be chemically adsorbed on the surface of the substrate and to form a SAM excellent in denseness.

According to the above configuration, it is preferable that the treating liquid generation portion adds the material containing the molecule that allows formation of the self-assembled monolayer to the dispersion liquid left still.

When the SAM forming material is added to the dispersion liquid, in a case where the addition is performed while a mechanical force such as stirring and shaking is applied to the dispersion liquid, the SAM molecules having the hydroxyl groups may be aggregated with each other. However, by adding the SAM forming material to the dispersion liquid in a state of being still to adjust the treating liquid by the treating liquid generation portion as in the above configuration, it is possible to further suppress the aggregation of the SAM molecules having the hydroxyl groups with each other and to generate the treating liquid.

In order to solve the above problem, a semiconductor manufacturing apparatus according to the present invention is a semiconductor manufacturing apparatus for performing a treatment of a substrate in which a stacked body is provided on a surface, the stacked body including layers in which a layer to be protected that is to be protected from etching and a layer to be etched that is to be etched are alternately stacked, the semiconductor manufacturing apparatus comprising a treating liquid generation portion that generates a treating liquid containing a molecule that allows formation of the self-assembled monolayer, an ultrasonic wave application portion; a treating liquid supply portion that supplies the treating liquid generated by the treating liquid generation portion to the surface of the substrate to form the self-assembled monolayer and an etching portion that selectively etches and removes the layer to be etched by using the self-assembled monolayer as a protective layer, wherein the treating liquid generation portion generates a dispersion liquid in which water is uniformly dispersed in an organic solvent as a main solvent, further adds a material containing a molecule that allows formation of the self-assembled monolayer to the dispersion liquid, and causes a hydrolysis reaction of the water dispersed in the dispersion liquid and a functional group to generate the treating liquid containing the molecule having a hydroxyl group and in which the molecule having the hydroxyl group exists without being aggregated, and the ultrasonic wave application portion applies an ultrasonic wave when or after the organic solvent and the water are mixed in the treating liquid generation portion to generate the dispersion liquid.

In the above configuration, the treating liquid generation portion mixes the organic solvent as the main solvent with water to generate a mixed liquid. Then, the ultrasonic wave application portion applies an ultrasonic wave when the treating liquid generation portion mixes the organic solvent with the water or applies an ultrasonic wave to a mixed liquid generated by mixing the organic solvent with the water. In this manner, the treating liquid generation portion can generate the dispersion liquid in which the water is uniformly dispersed in the organic solvent. Furthermore, the treating liquid generation portion adds the material SAM forming material containing the SAM molecules to the generated dispersion liquid without applying an ultrasonic wave to generate the treating liquid. Here, the SAM molecule has a functional group exhibiting hydrolysis reactivity, and water molecules are uniformly dispersed in the dispersion liquid. Therefore, when the SAM forming material is added to the dispersion liquid, the functional group exhibiting hydrolysis reactivity in the SAM molecules undergoes a hydrolysis reaction with the water molecules in the dispersion liquid to become a hydroxyl group (OH group). In this manner, a treating liquid containing a SAM molecule having a hydroxyl group can be produced. The treating liquid generation portion generates the treating liquid such that SAM molecules having hydroxyl groups exist without being aggregated with each other. By generating the treating liquid without applying ultrasonic waves, the treating liquid generation portion can generate the treating liquid such that SAM molecules having hydroxyl groups exist without being aggregated with each other. By generating the treating liquid such that the SAM molecules having the hydroxyl groups exist without being aggregated with each other, a self-assembled monolayer can be favorably formed on the surface of the substrate.

Furthermore, the treating liquid supply portion supplies the treating liquid to the surface of the substrate to bring the SAM molecules into contact with the surface of the substrate, and causes a dehydration condensation reaction between the hydroxyl group of the SAM molecules and the hydroxyl group existing on the surface of the substrate. As a result, the SAM molecules can be chemically adsorbed on the surface of the substrate, and the chemically adsorbed SAM molecules can be self-assembled to form a SAM. Furthermore, the etching portion selectively etches the layer to be etched by using the SAM as a protective layer.

As described above, in the above configuration, the hydroxyl group is introduced into the SAM molecules to be chemically adsorbed on the surface of the substrate by a hydrolysis reaction in advance at a generation stage of the treating liquid. Therefore, as compared with a case where the SAM is formed by using the SAM molecule to which the hydroxyl group is not introduced, the hydrolysis reaction of the SAM molecule, which is a rate-limiting step in a formation process of the SAM, can be omitted. Since the treating liquid contains the SAM molecules having hydroxyl groups without being aggregated, a dehydration condensation reaction between the SAM molecules having hydroxyl groups and the hydroxyl groups on the surface of the substrate also effectively occurs, the reaction being the rate-limiting step in the formation process of the SAM. Therefore, the SAM molecules can be chemically adsorbed on the surface of the substrate at high density. In this manner, in the above configuration, it is possible to suppress the occurrence of layer defects and efficiently form a SAM excellent in denseness and protection performance in a short time without bringing the SAM molecules into contact with the surface of the substrate for a long time in order to form a compact SAM as in a conventional semiconductor manufacturing apparatus. Then, since the layer to be protected can be protected by the SAM excellent in denseness and protection performance, the semiconductor manufacturing apparatus having the above configuration can favorably perform selective etching of the layer to be etched.

In order to solve the above problem, an another semiconductor manufacturing apparatus according to the present invention is a semiconductor manufacturing apparatus for performing a treatment of a substrate in which a stacked body is provided on a surface, the stacked body including layers in which a layer to be protected that is to be protected from etching and a layer to be etched that is to be etched are alternately stacked, the semiconductor manufacturing apparatus comprising a substrate treatment unit that selectively forms a self-assembled monolayer on at least a surface of the layer to be protected, and an etching treatment unit that selectively etches and removes the layer to be etched by using the self-assembled monolayer as a protective layer, wherein the substrate treatment unit includes a treating liquid generation portion that generates a treating liquid containing a molecule that allows formation of the self-assembled monolayer, an ultrasonic wave application portion, and a treating liquid supply portion that supplies the treating liquid generated by the treating liquid generation portion to the surface of the substrate to form the self-assembled monolayer, the treating liquid generation portion generates a dispersion liquid in which water is uniformly dispersed in an organic solvent as a main solvent, further adds a material containing a molecule that allows formation of the self-assembled monolayer to the dispersion liquid, and causes a hydrolysis reaction of the water dispersed in the dispersion liquid and the functional group to generate the treating liquid containing the molecule having a hydroxyl group and in which the molecule having the hydroxyl group exists without being aggregated, and the ultrasonic wave application portion applies an ultrasonic wave when or after the organic solvent and the water are mixed in the treating liquid generation portion to generate the dispersion liquid.

In the above configuration, the treating liquid generation portion in the substrate treatment unit mixes the organic solvent as the main solvent with water to generate a mixed liquid. Then, the ultrasonic wave application portion applies an ultrasonic wave when the treating liquid generation portion mixes the organic solvent with the water or applies an ultrasonic wave to a mixed liquid generated by mixing the organic solvent with the water. In this manner, the treating liquid generation portion can generate the dispersion liquid in which the water is uniformly dispersed in the organic solvent. Furthermore, the treating liquid generation portion adds the material SAM forming material containing the SAM molecules to the generated dispersion liquid without applying an ultrasonic wave to generate the treating liquid. Here, the SAM molecule has a functional group exhibiting hydrolysis reactivity, and water molecules are uniformly dispersed in the dispersion liquid. Therefore, when the SAM forming material is added to the dispersion liquid, the functional group exhibiting hydrolysis reactivity in the SAM molecules undergoes a hydrolysis reaction with the water molecules in the dispersion liquid to become a hydroxyl group (OH group). In this manner, a treating liquid containing a SAM molecule having a hydroxyl group can be produced. The treating liquid generation portion generates the treating liquid such that SAM molecules having hydroxyl groups exist without being aggregated with each other. By generating the treating liquid without applying ultrasonic waves, the treating liquid generation portion can generate the treating liquid such that SAM molecules having hydroxyl groups exist without being aggregated with each other. By generating the treating liquid such that the SAM molecules having the hydroxyl groups exist without being aggregated with each other, a self-assembled monolayer can be favorably formed on the surface of the substrate.

Furthermore, the treating liquid supply portion supplies the treating liquid to the surface of the substrate to bring the SAM molecules into contact with the surface of the substrate, and causes a dehydration condensation reaction between the hydroxyl group of the SAM molecules and the hydroxyl group existing on the surface of the substrate. As a result, the SAM molecules can be chemically adsorbed on the surface of the substrate, and the chemically adsorbed SAM molecules can be self-assembled to form a SAM. Furthermore, the etching treatment unit selectively etches the layer to be etched by using the SAM as a protective layer.

As described above, in the above configuration, the hydroxyl group is introduced into the SAM molecules to be chemically adsorbed on the surface of the substrate by a hydrolysis reaction in advance at a generation stage of the treating liquid. Therefore, as compared with a case where the SAM is formed by using the SAM molecule to which the hydroxyl group is not introduced, the hydrolysis reaction of the SAM molecule, which is a rate-limiting step in a formation process of the SAM, can be omitted. Since the treating liquid contains the SAM molecules having hydroxyl groups without being aggregated, a dehydration condensation reaction between the SAM molecules having hydroxyl groups and the hydroxyl groups on the surface of the substrate also effectively occurs, the reaction being the rate-limiting step in the formation process of the SAM. Therefore, the SAM molecules can be chemically adsorbed on the surface of the substrate at high density. In this manner, in the above configuration, it is possible to suppress the occurrence of layer defects and efficiently form a SAM excellent in denseness and protection performance in a short time without bringing the SAM molecules into contact with the surface of the substrate for a long time in order to form a compact SAM as in a conventional semiconductor manufacturing apparatus. Then, since the layer to be protected can be protected by the SAM excellent in denseness and protection performance, the semiconductor manufacturing apparatus having the above configuration can favorably perform selective etching of the layer to be etched.

According to the above configuration, an addition amount of the water when the organic solvent and the water are mixed in the treating liquid generation portion is preferably in a range of 50 ppm or more and 200 ppm or less.

By setting the addition amount of water to 50 ppm or more, it is possible to prevent the hydrolysis reaction of the functional group exhibiting hydrolysis reactivity in the SAM molecule from becoming insufficient, and it is possible to allow a sufficient amount of the SAM molecule into which the hydroxyl group is introduced to exist in the treating liquid. As a result, it is possible to suppress the occurrence of layer defects and form a SAM excellent in denseness without bringing SAM molecules into contact with the surface of the substrate for a long time in order to form a compact SAM as in the conventional semiconductor manufacturing apparatus. On the other hand, by setting the addition amount of water to 200 ppm or less, it is possible to suppress excessive aggregation of SAM molecules having a hydroxyl group due to a dehydration condensation reaction. As a result, it is possible to suppress a decrease in density of the SAM molecules to be chemically adsorbed on the surface of the substrate and to form a SAM excellent in denseness.

According to the above configuration, it is preferable that the treating liquid generation portion adds the material containing the molecule that allows formation of the self-assembled monolayer to the dispersion liquid left still.

When the SAM forming material is added to the dispersion liquid, in a case where the addition is performed while a mechanical force such as stirring and shaking is applied to the dispersion liquid, the SAM molecules having the hydroxyl groups may be aggregated with each other. However, by adding the SAM forming material to the dispersion liquid in a state of being still to adjust the treating liquid by the treating liquid generation portion as in the above configuration, it is possible to further suppress the aggregation of the SAM molecules having the hydroxyl groups with each other and to generate the treating liquid.

### Effects of the Invention

The present invention can provide a substrate treating method and a substrate treating apparatus capable of efficiently forming a self-assembled monolayer having high layer density, favorable suppression or reduction of occurrence of layer defects, and excellent in denseness and protection performance on a surface of a substrate in a shorter time than conventionally, a method for manufacturing a semiconductor apparatus, and a semiconductor manufacturing apparatus.

### BRIEF DESCRIPTION OF THE DRAWINGS

FIG. 1A is a sectional view schematically showing a stacked body provided on a substrate and showing a state before an etching step.

FIG. 1B is a sectional view schematically showing the stacked body provided on the substrate and showing a status after the etching step.

FIG. 2A is a partially enlarged view of a portion surrounded by A in the stacked body in FIG. 1A.

FIG. 2B is a partially enlarged view showing a status in which a SAM is formed on a surface of a SiO₂ layer.

FIG. 2C is a partially enlarged view of a portion surrounded by B in the stacked body in FIG. 1B, and shows a status in which a SiN layer is etched.

FIG. 3 is a flowchart showing an example of an overall flow of a method for manufacturing a semiconductor apparatus according to a first embodiment of the present invention.

FIG. 4A is a schematic diagram showing a status in which a treating liquid is supplied to the surface of the SiO₂ layer in the first embodiment.

FIG. 4B is a schematic diagram showing a status in which SAM molecules are chemically adsorbed on the surface of the SiO₂ layer in the first embodiment.

FIG. 4C is a schematic diagram showing a status in which the SAM molecules are self-assembled on the surface of the SiO₂ layer to form the SAM in the first embodiment.

FIG. 5A is a schematic diagram showing a status in which excessive SAM molecules are removed from the surface of the SiO₂ layer in a removal step.

FIG. 5B is a partially enlarged view showing a state in which the SAM is formed on the surface of the SiO₂ layer.

FIG. 6 is an explanatory diagram showing a schematic configuration of a semiconductor manufacturing apparatus according to the first embodiment of the present invention.

FIG. 7 is an explanatory diagram showing a schematic configuration of a treating liquid storage portion and an ultrasonic wave application portion in the semiconductor manufacturing apparatus according to the first embodiment of the present invention.

FIG. 8 is an explanatory diagram showing a schematic configuration of a removal liquid storage portion provided in a removal liquid supply portion in the semiconductor manufacturing apparatus according to the first embodiment of the present invention.

FIG. 9 is a block diagram showing a schematic configuration of an inert gas storage portion in an inert gas supply portion in the semiconductor manufacturing apparatus according to the first embodiment of the present invention.

FIG. 10 is an explanatory diagram showing a schematic configuration of an etching liquid storage portion in an etching liquid supply portion in the first embodiment of the present invention.

FIG. 11 is a flowchart showing an example of an overall flow of a method for manufacturing a semiconductor apparatus according to a second embodiment of the present invention.

FIG. 12 is a side view showing a schematic configuration of a lifter in a semiconductor manufacturing apparatus according to the second embodiment of the present invention.

FIG. 13 is a sectional view showing a status in which a plurality of substrates on which a SAM is formed is immersed in an etching liquid in the second embodiment of the present invention.

FIG. 14 is a graph showing a relationship between an addition amount (ppm) of water and an area ratio (%) of layer defects of the SAM in each sample of Example 1 to 3 and Comparative Examples 1 and 2.

### EMBODIMENTS OF THE INVENTION

### First Embodiment

A first embodiment of the present invention will be described below.

### [Substrate Treating Method (Method for Manufacturing Semiconductor Apparatus)]

First, a substrate treating method according to the present embodiment will be described below with reference to the drawings.

The substrate treating method according to the present embodiment provides, for example, a technique for enabling favorable selective etching in forming a three-dimensional structure such as a three-dimensional NAND structure on a surface of a substrate.

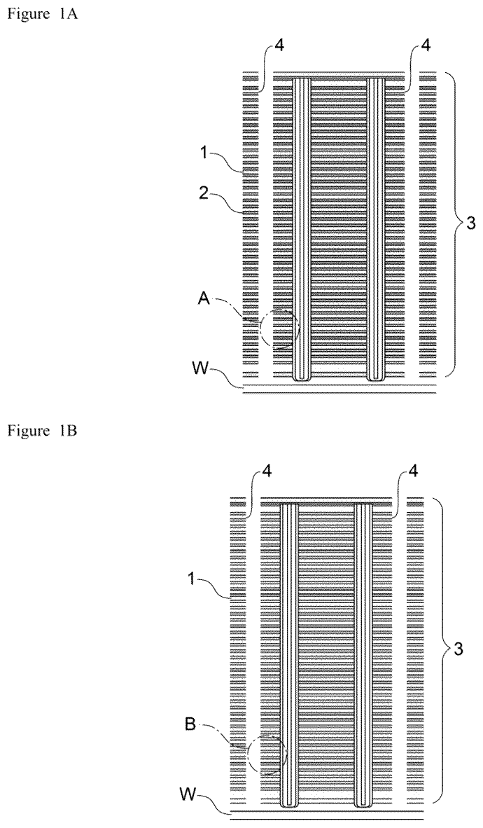

The substrate treating method according to the present embodiment can be applied to a part of a step of forming a three-dimensional NAND structure on a substrate W made of silicon or the like. Therefore, in the following description, an example will be described as an example in which the substrate treating method according to the present embodiment is applied to a method for manufacturing a semiconductor apparatus, specifically, a case of performing processing on the substrate W provided with a stacked body 3 having a three-dimensional structure as illustrated in FIG. 1. FIG. 1A is a sectional view schematically showing a stacked body provided on a substrate W, and shows a state before an etching step, and FIG. 1B shows a status after the etching step.

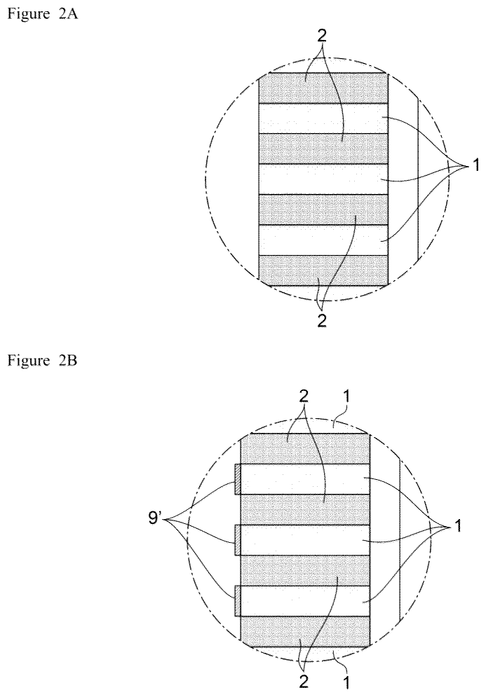

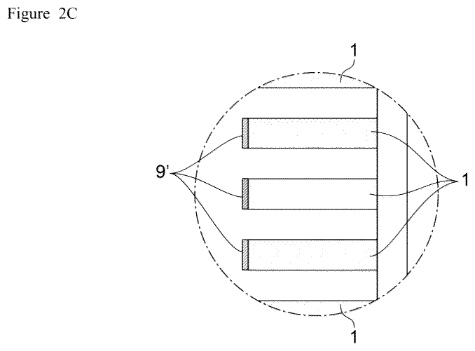

As illustrated in FIG. 2A, the stacked body 3 includes the substrate W on which SiO₂ layers 1 functioning as interlayer insulating layers and SiN layers 2 functioning as sacrificial layers are alternately stacked. The stacked body 3 is provided with a plurality of memory trenches 4 extending so as to penetrate the stacked body 3 in a direction perpendicular to the surface of the substrate W. FIG. 2A is a partially enlarged view of a portion surrounded by A in the stacked body in FIG. 1.

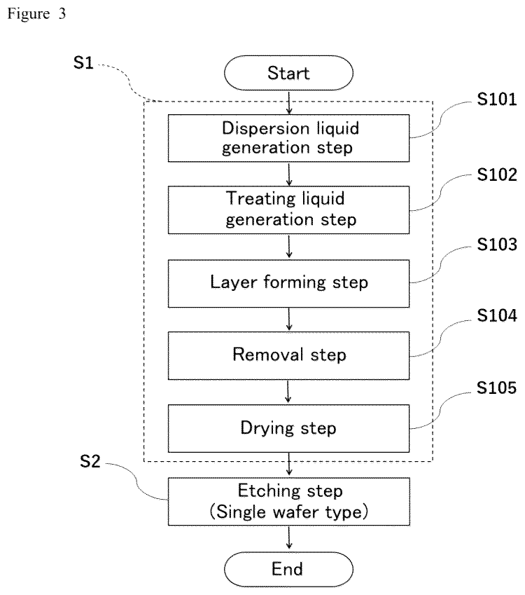

As illustrated in FIG. 3, the method for manufacturing the semiconductor apparatus according to the present embodiment includes at least a self-assembled monolayer (hereinafter referred to as “SAM”) forming step S1 and an etching step S2, selectively etches the SiN layer 2 with the memory trench 4 interposed therebetween, and makes it possible to form a recess on a side surface of the memory trench 4 in the stacked body 3. FIG. 3 is a flowchart showing an example of an overall flow of the method for manufacturing the semiconductor apparatus according to the present embodiment.

### <SAM Forming Step>

The SAM forming step S1 is a step of selectively forming a SAM as a protective layer on the surface of the SiO₂ layer 1 as a layer to be protected. As illustrated in FIG. 3, the SAM forming step S1 includes at least a dispersion liquid generation step S101, a treating liquid generation step S102, a layer forming step S103, a removal step S104, and a drying step S105. Note that the SAM forming step S1 corresponds to a substrate treating method of the present invention.

### 1. Dispersion Liquid Generation Step

The dispersion liquid generation step S101 is a step of generating a dispersion liquid in which water is uniformly dispersed in an organic solvent as a main solvent. The phrase “water is uniformly dispersed in an organic solvent” means that, for example, water exists in the organic solvent in an emulsion state. The “main solvent” means a solvent having the largest volume ratio when a mixed solvent including a plurality of solvents is used.

Examples of the organic solvent as the main solvent include ether solvents, aromatic hydrocarbon-based solvents, aliphatic hydrocarbon-based solvents, fluorine-based solvents, and ketone-based solvents. The ether solvent is not limited, and examples thereof include tetrahydrofuran (THF). The aromatic hydrocarbon-based solvent is not limited, and examples thereof include toluene. The aliphatic hydrocarbon-based solvent is not limited, and examples thereof include decane. The fluorine-based solvent is not limited, and examples thereof include 1,3-bis (trifluoromethyl)benzene. The ketone-based solvent is not limited, and examples thereof include methyl ethyl ketone. These solvents can be used alone or as a mixture of two or more kinds thereof. Among the exemplified solvents, from the viewpoint of affinity with water, an aromatic hydrocarbon-based solvent is preferable, and toluene is particularly preferable.

As the organic solvent as the main solvent, an organic solvent having a low water solubility is preferable. Thus, water can be well dispersed in the organic solvent. Examples of the organic solvent having low water solubility include the toluene mentioned above.

Examples of a method for generating the dispersion liquid include a method of mixing an organic solvent and water while applying an ultrasonic wave, and a method of mixing an organic solvent and water and then applying an ultrasonic wave. By applying an ultrasonic wave, it is possible to prevent generation of a mixed liquid phase-separated into an organic solvent phase and an aqueous phase. That is, by applying an ultrasonic wave, cavitation is generated in the organic solvent, and by disturbing an interface between the organic solvent and the water, the water is granulated. As a result, as compared with stirring and mixing to which a mechanical force such as stirring or shaking is applied, it is possible to generate a dispersion liquid in which water of fine particles is uniformly dispersed in an organic solvent and which is excellent in dispersion stability. In the present invention, addition of an emulsifier can be omitted when an ultrasonic wave is applied.

An addition amount of water in the dispersion liquid is preferably in a range of 50 ppm or more and 200 ppm or less, and more preferably in a range of 50 ppm or more and 150 ppm or less. By setting the addition amount of water to 50 ppm or more, it is possible to prevent a hydrolysis reaction of a functional group exhibiting hydrolysis reactivity from becoming insufficient in a SAM molecule added in the treating liquid generation step S102 described later. That is, at a generation stage of the treating liquid, a sufficient amount of SAM molecules into which a hydroxyl group is introduced can exist in the treating liquid. As a result, it is possible to suppress the occurrence of layer defects and form a SAM excellent in denseness without bringing SAM molecules into contact with the surface of the substrate for a long time in order to form a compact SAM as in the conventional substrate treating method. On the other hand, by setting the addition amount of water to 200 ppm or less, it is possible to suppress excessive aggregation of SAM molecules having a hydroxyl group due to a dehydration condensation reaction. As a result, it is possible to suppress a decrease in density of the SAM molecules to be chemically adsorbed on the surface of the substrate and to form a SAM excellent in denseness.

The dispersion liquid generation step S101 is preferably performed, for example, in an atmosphere of an inert gas such as nitrogen gas. When this step is performed in an environment in which moisture exists in the atmosphere, the moisture in the atmosphere is dissolved in the mixed liquid (or the dispersion liquid), and as a result, a dispersion liquid having a predetermined moisture amount cannot be obtained, which is not preferable.

Conditions for applying ultrasonic waves in the dispersion liquid generation step S101, specifically, for example, application time, frequency, sound wave intensity, and the like are not limited as long as water is dispersed in the organic solvent, and can be appropriately set as necessary. A method of applying an ultrasonic wave is not limited, and examples thereof include a method in which an ultrasonic transducer is immersed in a mixed liquid, and the ultrasonic transducer is vibrated to apply an ultrasonic wave.

### 2. Treating Liquid Generation Step

The treating liquid generation step S102 is a step of generating a treating liquid containing SAM molecules. The treating liquid is used to form a SAM on the surface of the SiO₂ layer 1 as a layer to be protected. Specifically, the generation of the treating liquid is performed by adding a material capable of forming SAM (hereinafter referred to as a “SAM forming material”) to the dispersion liquid prepared in the dispersion liquid generation step S101. When the SAM forming material is added to the dispersion liquid, and after the SAM forming material is added to the dispersion liquid, this step is preferably performed without applying an ultrasonic wave. By not applying an ultrasonic wave, the treating liquid can be generated such that the SAM molecules exist without being aggregated with each other. By generating the treating liquid such that the SAM molecules exist without being aggregated with each other, a self-assembled monolayer can be favorably formed in the layer forming step.

The SAM forming material is not limited as long as the material has a functional group exhibiting hydrolysis reactivity and contains a molecule capable of forming a SAM. As the SAM forming material, a material having high affinity (solubility) with the above organic solvent mentioned above is preferable. Specifically, the SAM forming material is, for example, an organosilane compound such as octadecyltrichlorosilane. Octadecyltrichlorosilane is a compound having a trichlorosilyl group as a functional group exhibiting hydrolysis reactivity.

The SAM molecule before being added to the treating liquid has a functional group exhibiting hydrolysis reactivity. Therefore, when the SAM forming material is added to the dispersion liquid, the functional group causes a hydrolysis reaction with water molecules uniformly dispersed in the dispersion liquid. As a result, the functional group exhibiting hydrolysis reactivity in the SAM molecule becomes a hydroxyl group (OH group). For example, when the SAM molecule is octadecyltrichlorosilane, the following reaction occurs.

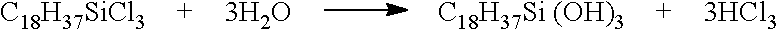

As a result, it is possible to obtain a treating liquid in which the SAM molecules into which the hydroxyl groups have been introduced exist without being aggregated. Thereby, by preparing a treating liquid containing SAM molecules into which hydroxyl groups are introduced in advance, it is possible to omit the hydrolysis reaction which is a rate-limiting step in a formation process of the SAM. As a result, the SAM can be formed in a shorter time than with a conventional treating liquid.

The addition amount of the SAM forming material is preferably in a range of 0.05 mass % or more and 5 mass % or less of a total mass of the treating liquid. The treating liquid may contain a known additive as long as the effect of the present invention is not impaired. The additive is not limited, and examples thereof include a stabilizer, a surfactant and the like.

The treating liquid generation step is preferably performed in a state of being still. Specifically, when the SAM forming material is added to the dispersion liquid, it is not preferable to add the SAM forming material to the dispersion liquid while applying a mechanical force such as stirring and shaking to the dispersion liquid. When the SAM forming material is added to the dispersion liquid, in a case where the addition is performed while a mechanical force such as stirring and shaking is applied to the dispersion liquid, the SAM molecules may be aggregated with each other. However, by adding the SAM forming material to the dispersion liquid in a state of being still to adjust the treating liquid, it is possible to further suppress the aggregation of the SAM molecules with each other and to generate the treating liquid.

The content of water in the treating liquid is preferably in the range of 50 ppm or more and 200 ppm or less, and more preferably in the range of 50 ppm or more and 150 ppm or less, as described in the explanation about the dispersion liquid generation step.

The treating liquid generation step S102 can be performed, for example, at normal temperature and normal pressure.

### 3. Layer Forming Step

The layer forming step S103 is a step of bringing the treating liquid containing the SAM forming material into contact with the surface of the substrate W to form a SAM.

The method of bringing the treating liquid into contact with the substrate W is not particularly limited, and examples thereof include a method of applying the treating liquid to the surface of the substrate W, a method of spraying the treating liquid to the surface of the substrate W, a method of immersing the substrate W in the treating liquid and the like.

Examples of the method of applying the treating liquid to the surface of the substrate W include a method of supplying the treating liquid to a central portion of the surface of the substrate W in a state where the substrate W is rotated at a constant speed with the central portion as an axis. In this manner, the treating liquid supplied to the surface of the substrate W flows from near a center of the surface of the substrate W toward a peripheral edge of the substrate W by a centrifugal force generated by the rotation of the substrate W, and is diffused over the entire surface of the substrate W. As a result, the entire surface of the substrate W is covered with the treating liquid, and a liquid film of the treating liquid is formed.

The condition for bringing the treating liquid into contact with the substrate W is not limited. However, in the layer forming step S103 according to the present embodiment, time for a contact of the treating liquid can be shortened as compared with the case of forming the SAM by a conventional method. Specifically, the time required for the SAM forming step S1 (in a case where the substrate W is immersed in the treating liquid, an immersion time) can be appropriately set within a range of 1 minute to 1440 minutes, preferably 1 minute to 60 minutes, and more preferably 1 minute to 30 minutes in accordance with the type of the SAM forming material, the concentration of the SAM forming material, the type of the solvent, and the like.

Next, the formation process of the SAM will be described specifically by taking as an example a case where the SAM forming material is octadecyltrichlorosilane.

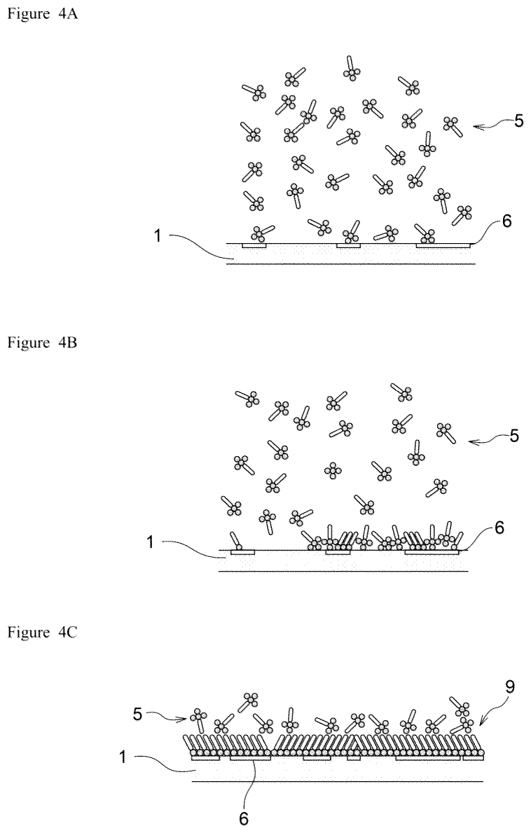

As illustrated in FIG. 4A, when the treating liquid is supplied to the surface of the substrate W, SAM molecules 5 in which a hydroxyl group is introduced into octadecyltrichlorosilane are dispersed in the treating liquid at the beginning of the supply. FIG. 4A is a schematic diagram showing a status in which the treating liquid is supplied to the surface of the SiO₂ layer 1.

Next, when a hydroxyl group (OH group) 6 exists on the surface of the SiO₂ layer 1, the SAM molecule 5 undergoes a dehydration condensation reaction with the hydroxyl group 6 as illustrated in FIG. 4B. More specifically, the hydroxyl group of the SAM molecule 5 and the hydroxyl group 6 on the surface of the SiO₂ layer 1 undergo a dehydration condensation reaction to form a siloxane bond, and thus, the SAM molecule 5 is chemically adsorbed on the surface of the SiO₂ layer 1. The SAM molecules 5 exist in a state where aggregation with each other is suppressed in the treating liquid. It is therefore possible to promote the dehydration condensation reaction between the hydroxyl group of the SAM molecule 5 and the hydroxyl group on the surface of the SiO₂ layer 1, which is the rate-limiting step in the formation process of the SAM. The SAM molecules 5 can be chemically adsorbed on the surface of the SiO₂ layer 1 at a high density. FIG. 4B is a schematic diagram showing a status in which SAM molecules 5 are chemically adsorbed on the surface of the SiO₂ layer 1.

Subsequently, when the SAM molecules 5 are chemically adsorbed at a high density on the surface of the SiO₂ layer 1, an island-like structure of the SAM molecules 5 appears on the surface. Furthermore, in each island, the SAM molecules 5 self-assemble and grow (expand) by hydrophobic interaction or electrostatic interaction between the SAM molecules 5, and a SAM 9 is finally formed (see FIG. 4C). FIG. 4C is a schematic diagram showing a status in which the SAM molecules 5 are self-assembled on the surface of the SiO₂ layer 1 to form the SAM 9.

### 4. Removal Step

The removal step S104 is a step of removing the treating liquid remaining on the surface of the SiO₂ layer 1 after the layer forming step S103. In this manner, the SAM molecules 5 that are excessive and do not contribute to the formation of the SAM 9, specifically, the SAM molecules 5 that are not chemically adsorbed on the surface of the SiO₂ layer 1 can be removed. As a result, a layer including the unadsorbed SAM molecules 5 is prevented from being formed on the SAM 9, and a favorable monolayer can be formed.

The method of removing the treating liquid from the surface of the SiO₂ layer 1 is not particularly limited, and examples thereof include a method of applying the removal liquid to the surface of the substrate W, a method of spraying the removal liquid to the surface of the substrate W, a method of immersing the substrate W in the removal liquid and the like.

Examples of the method of applying the removal liquid to the surface of the substrate W include a method of supplying the removal liquid to a central portion of the surface of the substrate W in a state where the substrate W is rotated at a constant speed with the central portion as an axis. In this manner, the removal liquid supplied to the surface of the substrate W flows from near the center of the surface of the substrate W toward the peripheral edge of the substrate W by the centrifugal force generated by the rotation of the substrate W, and is diffused over the entire surface of the substrate W. As a result, the treating liquid on the surface of the substrate W is replaced with the removal liquid, the entire surface of the substrate W is covered with the removal liquid, and a liquid film of the removal liquid is formed.

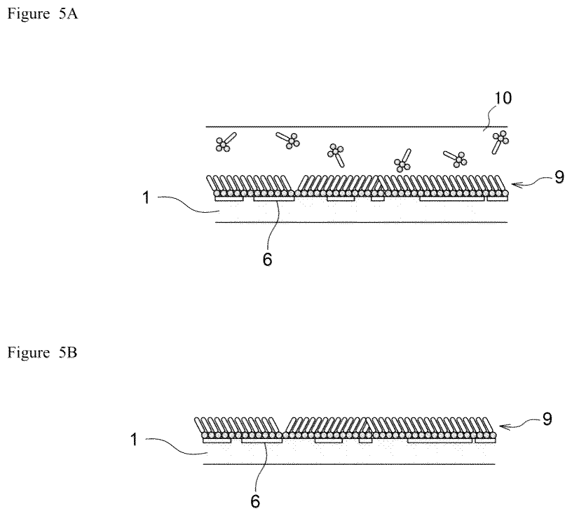

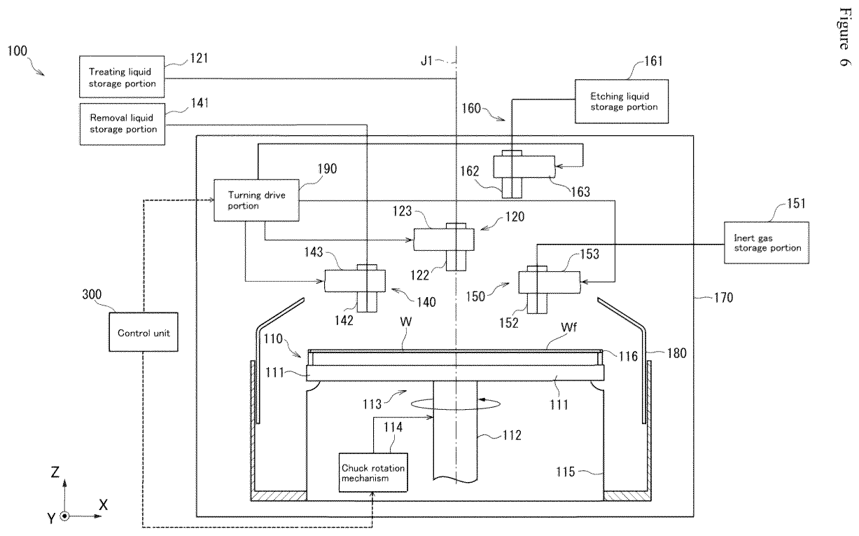

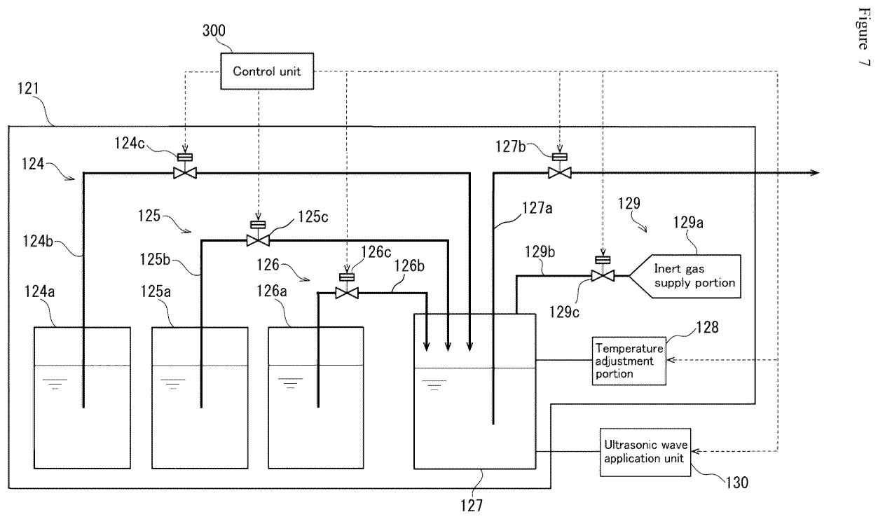

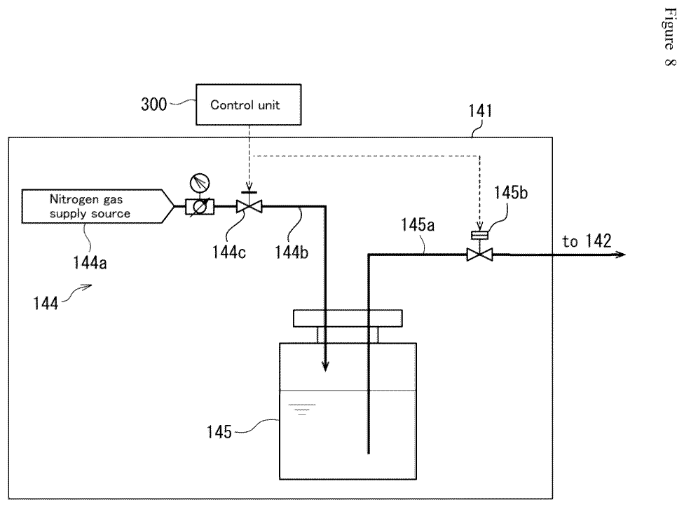

When the SAM forming material is octadecyltrichlorosilane, the surface of the SiO₂ layer 1 in the removal step S104 is as illustrated in FIG. 5A. As illustrated in the drawing, the SAM molecules 5 that do not contribute to the layer formation of the SAM 9 are removed from the surface of the SiO₂ layer 1 of the substrate W by a removal liquid 10. FIG. 5A is a schematic diagram showing a status in which the excessive SAM molecules 5 are removed from the surface of the SiO₂ layer 1 in the removal step S104.

The removal liquid is not limited, but an organic solvent that dissolves the SAM forming material and has a low water solubility is preferable. When the removal liquid is capable of dissolving the SAM forming material, the SAM molecules 5 that are excessive and do not contribute to the formation of the SAM can be favorably removed from the surface. Specific examples of the removal liquid include toluene, decane, 1,3-bis(trifluoromethyl)benzene and the like. These solvents can be used alone or as a mixture of two or more kinds thereof.

### 5. Drying Step

An object of the drying step S105 is to remove the removal liquid remaining on the surface of the substrate W. The drying method is not limited, and examples thereof include a method of spraying an inert gas such as nitrogen gas onto the surface of the substrate W. Drying conditions such as a drying time and a drying temperature are not limited as long as the removal liquid is removed, and can be appropriately set as necessary.

As described above, in the SAM forming step S1, as illustrated in FIG. 5B, the SAM 9 excellent in denseness and protection performance can be formed on the surface of the SiO₂ layer 1. FIG. 5B is a partially enlarged view showing a state in which the SAM 9 is formed on the surface of the SiO₂ layer 1. In the SAM forming step S1, the treating liquid containing the SAM molecule into which a hydroxyl group is introduced in advance is used to form the SAM 9 on the surface of the SiO₂ layer 1. In this manner, it is possible to prevent the hydrolysis reaction of the SAM molecule, which is the rate-limiting step in the formation of the SAM 9, from being performed in the forming step of the SAM 9. Since the SAM molecules 5 in the treating liquid exist without being aggregated, the dehydration condensation reaction with the hydroxyl group on the surface of the SiO₂ layer 1 can also efficiently occur, the reaction being the rate-limiting step in the formation of the SAM 9. As a result, in order to form a compact layer, it is possible to suppress the occurrence of layer defects and efficiently form the SAM 9 excellent in denseness and protection performance in a short time without bringing the SAM molecules 5 into contact with the surface of the SiO₂ layer 1 for a long time.

In the present embodiment, immediately after the drying step S105, a rinsing step and another drying step may be further performed. By performing the rinsing step, the removal liquid can be removed from the surface of the SiO₂ layer 1. A rinsing liquid used in the rinsing step can be removed by performing another drying step.

The rinsing liquid in the rinsing step is not limited, and examples thereof include DIW. A method of supplying the rinsing liquid to the surface of the substrate W is not limited, and examples thereof include a method of applying the rinsing liquid to the surface of the substrate W, a method of spraying the rinsing liquid to the surface of the substrate W, a method of immersing the substrate W in the rinsing liquid and that like.

Examples of the method of applying the rinsing liquid to the surface of the substrate W include a method of supplying the rinsing liquid to the central portion of the surface of the substrate W in a state where the substrate W is rotated at a constant speed with the central portion as an axis. In this manner, the rinsing liquid supplied to the surface of the substrate W flows from near the center of the surface of the substrate W toward the peripheral edge of the substrate W by the centrifugal force generated by the rotation of the substrate W, and is diffused over the entire surface of the substrate W. As a result, the removal liquid on the surface of the substrate W is replaced with the rinsing liquid, the entire surface of the substrate W is covered with the rinsing liquid, and a liquid film of the rinsing liquid is formed.

An object of another drying step is to remove the rinsing liquid remaining on the surface of the substrate W. The drying method is not limited, and examples thereof include a method of spraying an inert gas such as nitrogen gas onto the surface of the substrate W. Drying conditions such as a drying time and a drying temperature are not limited as long as the rinsing liquid is removed, and can be appropriately set as necessary.

### <Etching Step>

The etching step S2 is a step of selectively etching the SiN layer 2 which is a sacrificial layer and a layer to be etched. Specifically, the step is a step of bringing an etching liquid into contact with the SiN layer 2 with the memory trench 4 interposed therebetween to remove the SiN layer 2. In this step, the SAM 9 functions of protecting the SiO₂ layer 1 as a protective layer. It is therefore possible to favorably prevent the SiO₂ layer 1 from being etched.

Examples of the method of applying the etching liquid to the surface of the substrate W include a method of supplying the etching liquid to the central portion of the surface of the substrate W in a state where the substrate W is rotated at a constant speed with the central portion as an axis. In this manner, the etching liquid supplied to the surface of the substrate W flows from near the center of the surface of the substrate W toward the peripheral edge of the substrate W by the centrifugal force generated by the rotation of the substrate W, and is diffused over the entire surface of the substrate W. As a result, the entire surface of the substrate W is covered with the etching liquid, and a liquid film of the etching liquid is formed.

The etching liquid can be appropriately set in consideration of a constituent material of the layer to be etched, an etching rate, and the like. When the layer to be etched is the SiN layer 2 as in the present embodiment, for example, a phosphoric acid (H₃PO₄) aqueous solution, hydrofluoric acid (for example, HF:DIW=1:100 by volume), or the like can be used as the etching liquid. The concentration of the etching liquid can be appropriately set in consideration of the constituent material of the layer to be etched, the etching rate, and the like.

An etching temperature (that is, a liquid temperature of the etching liquid) and the etching rate for the layer to be etched can be appropriately set in consideration of the constituent material of the layer to be etched.

The rinsing step and the drying step for removing the etching liquid are preferably sequentially performed immediately after the etching step S2. The rinsing method in the rinsing step is not limited, and examples thereof include a method of supplying the rinsing liquid to the surface of the substrate W, a method of immersing the substrate W in the rinsing liquid and that like. The rinsing liquid is not limited, and examples thereof include DIW. Cleaning conditions such as a rinse time and a temperature of the rinsing liquid are not limited, and can be appropriately set as necessary. An object of the drying step is to remove the rinsing liquid remaining on the surface of the substrate W. The drying method is not limited, and examples thereof include a method of spraying an inert gas such as nitrogen gas onto the surface of the substrate W. Drying conditions such as the drying time and the drying temperature are not limited, and can be appropriately set as necessary.

As described above, in the etching step S2, as illustrated in FIG. 2C, only the SiN layer 2 can be selectively removed. Since the surface of the SiO₂ layer 1 is covered and protected by the SAM 9 excellent in denseness and protection performance, it is possible to prevent the SiO₂ layer 1 from being etched or an etched silicon component from being deposited and adhering to the surface of the SiO₂ layer 1. Furthermore, an allowable range of a concentration of silicon contained in the etching liquid such as phosphoric acid can also be increased. FIG. 2C is a partially enlarged view of a portion surrounded by B in the stacked body in FIG. 1B, and shows a state in which the SiN layer 2 is etched.

### [Substrate Treating Apparatus (Semiconductor Manufacturing Apparatus)]

Next, a substrate treating apparatus according to the present embodiment will be described below by exemplifying a case where the substrate treating apparatus is applied to a semiconductor manufacturing apparatus.

A semiconductor manufacturing apparatus 100 according to the present embodiment is a single wafer type treating unit used to form a SAM and to etch a layer to be etched, and includes, as illustrated in FIG. 6, a substrate holding portion 110 that holds the substrate W, a treating liquid generation portion that generates a treating liquid to be supplied to a front surface Wf of the substrate W, a treating liquid supply portion 120 that supplies the treating liquid to the front surface Wf of the substrate W, an ultrasonic wave application portion, a removal liquid supply portion 140 that supplies the removal liquid, an inert gas supply portion 150 that supplies an inert gas, an etching liquid supply portion (etching portion) 160, a chamber 170 that is a container that accommodates the substrate W, a dispersion prevention cup 180 that collects the treating liquid, a turning drive portion 190 that independently swings arms described later of each portion, and a control unit 300. The semiconductor manufacturing apparatus 100 can also include a loading/unloading means (not illustrated) that loads or unloads the substrate W. FIG. 6 is an explanatory diagram showing a schematic configuration of the semiconductor manufacturing apparatus 100 according to the present embodiment. In the drawing, XYZ orthogonal coordinate axes are appropriately shown in order to clarify a directional relationship as in the drawing. Here, an XY plane represents a horizontal plane, and a +Z direction represents a vertically upward direction.

### <Substrate Holding Portion>

The substrate holding portion 110 is a means that holds the substrate W, and as illustrated in FIG. 6, rotates the substrate W while holding the substrate W in a substantially horizontal orientation with the front surface Wf of the substrate W facing upward. The substrate holding portion 110 includes a spin chuck 113 in which a spin base 111 and a rotation support shaft 112 are integrally coupled. The spin base 111 has a substantially circular shape in plan view, and a hollow rotation support shaft 112 extending in a substantially vertical direction is fixed to a central portion of the spin base 111. The rotation support shaft 112 is connected to a rotation axis of a chuck rotation mechanism 114 including a motor. The chuck rotation mechanism 114 is accommodated in a cylindrical casing 115, and the rotation support shaft 112 is rotatably supported by the casing 115 a rotation axis J1 in the vertical direction.

The chuck rotation mechanism 114 can rotate the rotation support shaft 112 about the rotation axis J1 by driving from a chuck driving unit (not illustrated) of the control unit 300. As a result, the spin base 111 attached to an upper end of the rotation support shaft 112 rotates around the rotation axis J1 at a constant speed. The control unit 300 can control the chuck rotation mechanism 114 via the chuck drive unit to adjust a rotational speed of the spin base 111.

A plurality of chuck pins 116 for gripping a peripheral end of the substrate W are erected near a peripheral edge of the spin base 111. The number of chuck pins 116 to be installed is not limited, but at least three chuck pins are preferably provided in order to reliably hold the circular substrate W. In the present embodiment, three chuck pins 116 are arranged at equal intervals along the peripheral edge of the spin base 111. Each of the chuck pins 116 includes a substrate support pin that supports the peripheral edge of the substrate W from below, and a substrate holding pin that presses an outer peripheral end surface of the substrate W supported by the substrate support pin to hold the substrate W.

### <Treating Liquid Generation Portion>

The treating liquid generation portion according to the present embodiment is a means that generates the treating liquid to be supplied to the front surface Wf of the substrate W. As illustrated in FIG. 6, the treating liquid generation portion includes a treating liquid storage portion 121.

As illustrated in FIG. 7, the treating liquid storage portion 121 includes an organic solvent supply portion 124, a water supply portion 125, a SAM forming material supply portion 126, a treating liquid tank 127, a temperature adjustment portion 128, and an inert gas supply portion 129. FIG. 7 is an explanatory diagram showing a schematic configuration of the treating liquid storage portion 121 and an ultrasonic wave application portion 130.

The organic solvent supply portion 124 includes an organic solvent storage portion 124a that stores an organic solvent, an organic solvent supply pipe 124b for supplying the organic solvent to the treating liquid tank 127, and a valve 124c provided in the middle of the path of the organic solvent supply pipe 124b. The valve 124c is electrically connected to the control unit 300. Thus, opening and closing of the valve 124c can be controlled by an operation command of the control unit 300. When the valve 124c is opened in response to the operation command of the control unit 300, the organic solvent is supplied to the treating liquid tank 127 via the organic solvent supply pipe 124b. The organic solvent in the organic solvent storage portion 124a is pressurized by a pressurizing means (not illustrated) and sent to the organic solvent supply pipe 124b. The pressurizing means is not limited, and a known means such as a pump can be used.

The water supply portion 125 includes a water storage portion 125a that stores water, a water supply pipe 125b for supplying the water to the treating liquid tank 127, and a valve 125c provided in the middle of the path of the water supply pipe 125b. The valve 125c is electrically connected to the control unit 300. Thus, opening and closing of the valve 125c can be controlled by an operation command of the control unit 300. When the valve 125c is opened in response to the operation command of the control unit 300, the water is supplied to the treating liquid tank 127 via the water supply pipe 125b. The water in the water storage portion 125a is pressurized by a pressurizing means (not illustrated) and sent to the water supply pipe 125b. The pressurizing means is not limited, and a known means such as a pump can be used.

The SAM forming material supply portion 126 includes a SAM forming material storage portion 126a that stores the SAM forming material, a SAM forming material supply pipe 126b for supplying the SAM forming material to the treating liquid tank 127, and a valve 126c provided in the middle of the path of the SAM forming material supply pipe 126b. The valve 126c is electrically connected to the control unit 300. Thus, opening and closing of the valve 126c can be controlled by an operation command of the control unit 300. When the valve 126c is opened in response to the operation command of the control unit 300, the SAM forming material is supplied to the treating liquid tank 127 via the SAM forming material supply pipe 126b. Note that the SAM forming material in the SAM forming material storage portion 126a is pressurized by a pressurizing means (not illustrated) and sent to the SAM forming material supply pipe 126b. The pressurizing means is not limited, and a known means such as a pump can be used.

The treating liquid tank 127 mixes the organic solvent supplied from the organic solvent supply portion 124 with the water supplied from the water supply portion 125, and the ultrasonic wave application portion 130 applies an ultrasonic wave to the obtained mixed liquid to generate a dispersion liquid in which the water is uniformly dispersed in the organic solvent. The dispersion liquid can also be generated by applying an ultrasonic wave by the ultrasonic wave application portion 130 while mixing the organic solvent supplied from the organic solvent supply portion 124 and the water supplied from the water supply portion 125. Furthermore, the treating liquid can be generated by supplying the SAM forming material from the SAM forming material supply portion 126 in a state where the generated dispersion liquid is stored.

The treating liquid tank 127 may include the temperature adjustment portion 128 for adjusting the temperature of the dispersion liquid or the treating liquid stored therein. The temperature adjustment portion 128 is electrically connected to the control unit 300. The control unit 300 issues an operation command to the temperature adjustment portion 128, and the liquid temperature of the dispersion liquid can be controlled when the dispersion liquid is generated. It is thus possible to prevent water in the dispersion liquid from vaporizing (evaporating) to cause a change in composition of the dispersion liquid.

The inert gas supply portion 129 includes an inert gas supply portion 129a as a supply source for supplying an inert gas into the treating liquid tank 127, a pump (not illustrated) that pressurizes the inert gas, an inert gas supply pipe 129b, and a valve 129c provided in the middle of the path of the inert gas supply pipe 129b.

The inert gas supply pipe 129b is connected to the treating liquid tank 127 through a pipe line. The valve 129c is electrically connected to the control unit 300, and opening and closing of the valve 129c can be controlled by an operation command of the control unit 300. When the valve is opened in response to the operation command of the control unit 300, the inert gas can be supplied to the treating liquid tank 127. Thus, the dispersion liquid and the treating liquid can be generated under the atmosphere of the inert gas. The inert gas is not limited, and examples thereof include nitrogen gas.

Furthermore, a discharge pipe 127a for supplying the treating liquid to a nozzle 122 described later is connected to the treating liquid tank 127 through a pipe line. An exhaust valve 127b is provided in a middle path of the discharge pipe 127a. The exhaust valve 127b is electrically connected to the control unit 300. Thus, opening and closing of the exhaust valve 127b can be controlled by an operation command of the control unit 300. When the exhaust valve 127b and the valve 129c are opened and the valves 124c, 125c, and 126c are closed in response to the operation command of the control unit 300, the treating liquid is pressure-fed to the nozzle 122 via the discharge pipe 127a.

### <Treating Liquid Supply Portion>

The treating liquid supply portion 120 according to the present embodiment includes the nozzle 122 and an arm 123. The nozzle 122 is attached to a distal end of the arm 123 extending horizontally, and is disposed above the spin base 111 when the treating liquid is discharged. The arm 123 is coupled to the turning drive portion 190 via a swing shaft (not illustrated). The turning drive portion 190 is electrically connected to the control unit 300, and pivots the arm 123 in accordance with an operation command from the control unit 300. As the arm 123 pivots, the nozzle 122 also moves.

### <Ultrasonic Wave Application Portion>

As illustrated in FIG. 7, the ultrasonic wave application portion 130 is a means that applies an ultrasonic wave when the dispersion liquid is generated in the treating liquid tank 127. The ultrasonic wave application portion 130 is electrically connected to the control unit 300, and application of an ultrasonic wave can be controlled by an operation command of the control unit 300.

The ultrasonic wave application portion 130 includes, for example, at least an ultrasonic transducer provided in the treating liquid tank 127 and an oscillator that applies a drive voltage to the ultrasonic transducer (which are not illustrated). Examples of the ultrasonic transducer include a transducer including a piezoelectric body such as piezoelectric ceramics and a pair of electrodes provided on the piezoelectric body. The pair of electrodes is in contact with the piezoelectric body and is also electrically connected to the oscillator. When the oscillator outputs, for example, a high-frequency voltage as a drive voltage to an ultrasonic transducer in response to an operation command of the control unit 300, the drive voltage is applied between the pair of electrodes, and the drive voltage is thus applied to the piezoelectric body. The piezoelectric body to which the drive voltage is applied vibrates by alternately repeating contraction and expansion in accordance with the drive voltage from the oscillator. As a result, an ultrasonic wave can be applied to the mixed liquid of the water and the organic solvent stored in the treating liquid tank 127.

### <Removal Liquid Supply Portion>

The removal liquid supply portion 140 according to the present embodiment is a means that supplies the removal liquid to the front surface Wf of the substrate W. As illustrated in FIG. 6, the removal liquid supply portion 140 includes a removal liquid storage portion 141, a nozzle 142, and an arm 143.

As illustrated in FIG. 8, the removal liquid storage portion 141 has a function of supplying the removal liquid to the nozzle 142, and includes a pressurization portion 144 and a removal liquid tank 145. FIG. 8 is an explanatory diagram showing a schematic configuration of the removal liquid storage portion 141 in the removal liquid supply portion 140.

The pressurization portion 144 includes a nitrogen gas supply source 144a as a supply source of gas that pressurizes the inside of the removal liquid tank 145, a pump (not illustrated) that pressurizes nitrogen gas, a nitrogen gas supply pipe 144b, and a valve 144c provided in the middle of the path of the nitrogen gas supply pipe 144b.

The nitrogen gas supply pipe 144b is connected to the removal liquid tank 145 through a pipe line. The valve 144c is electrically connected to the control unit 300, and opening and closing of the valve 144c can be controlled by an operation command of the control unit 300. When the valve 144c is opened in response to the operation command of the control unit 300, the nitrogen gas can be supplied to the removal liquid tank 145.

The removal liquid tank 145 may include a stirring portion that stirs the removal liquid in the removal liquid tank 145 and a temperature adjustment portion that adjusts the temperature of the removal liquid (neither is illustrated). Examples of the stirring portion include a rotation portion that stirs the removal liquid in the removal liquid tank 145 and a stirring control unit that controls rotation of the rotation portion. The stirring control unit is electrically connected to the control unit 300, and the rotation portion includes, for example, a propeller-like stirring blade at the lower end of the rotation shaft. The control unit 300 gives an operation command to the stirring control unit to rotate the rotation portion, whereby the removal liquid can be stirred by the stirring blade. As a result, the concentration and temperature of the removal liquid can be made uniform in the removal liquid tank 145.

Furthermore, a discharge pipe 145a for supplying the removal liquid to the nozzle 142 is connected to the removal liquid tank 145 through a pipe line. An exhaust valve 145b is provided in a middle path of the discharge pipe 145a. The exhaust valve 145b is electrically connected to the control unit 300. Thus, opening and closing of the exhaust valve 145b can be controlled by an operation command of the control unit 300. When the exhaust valve 145b is opened in response to the operation command of the control unit 300, the removal liquid is pressure-fed to the nozzle 142 via the discharge pipe 145a.

The nozzle 142 is attached to the distal end portion of the arm 143 that is horizontally extended, and is disposed above the spin base 111 when the removal liquid is discharged. The arm 143 is coupled to the turning drive portion 190 via a turning shaft (not illustrated). The turning drive portion 190 is electrically connected to the control unit 300, and rotates the arm 143 according to an operation command from the control unit 300. The nozzle 142 also moves as a result of the rotation of the arm 143.

### <Inert Gas Supply Portion>

The inert gas supply portion 150 is a means that supplies the inert gas to the front surface Wf of the substrate W. As illustrated in FIG. 6, the inert gas supply portion 150 includes an inert gas storage portion 151, a nozzle 152, and an arm 153.

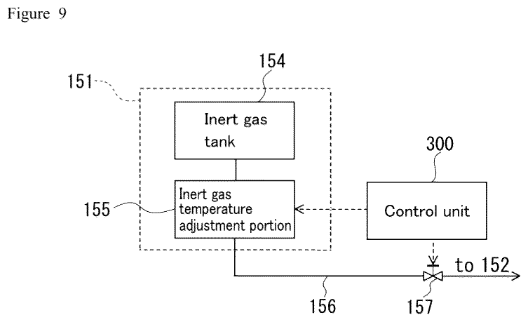

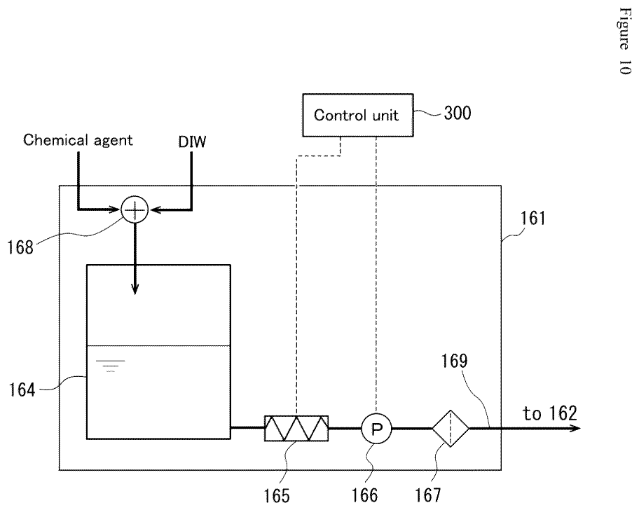

As illustrated in FIG. 9, the inert gas storage portion 151 has a function of supplying an inert gas to the nozzle 152, and includes an inert gas tank 154 that stores the inert gas, an inert gas temperature adjustment portion 155 that adjusts the temperature of the inert gas stored in the inert gas tank 154, and a pipe 156. Examples of the inert gas stored in the inert gas tank 154 include nitrogen gas. FIG. 9 is a block diagram showing a schematic configuration of the inert gas storage portion 151 in the inert gas supply portion 150.

The inert gas temperature adjustment portion 155 is electrically connected to the control unit 300, and performs temperature adjustment by heating or cooling the inert gas stored in the inert gas tank 154 in response to an operation command of the control unit 300. The inert gas temperature adjustment portion 155 is not limited, and for example, a known temperature adjustment mechanism such as a Peltier element or a pipe through which temperature-adjusted water passes can be used.

The inert gas storage portion 151 is connected to the nozzle 152 through the pipe 156, and a valve 157 is inserted in the middle of the path of the pipe 156. The inert gas in the inert gas tank 154 is pressurized by a pressurizing means (not illustrated) and sent to the pipe 156. The pressurizing means can also be implemented by compressing and storing an inert gas in the inert gas tank 154 in addition to pressurization by a pump or the like.

The valve 157 is electrically connected to the control unit 300, and is normally closed. Opening and closing of the valve 157 is controlled by an operation command of the control unit 300. When the valve 157 is opened in response to the operation command of the control unit 300, the inert gas is supplied from the nozzle 152 to the front surface Wf of the substrate W through the pipe 156.

The nozzle 152 is attached to a distal end of the arm 153 extending horizontally, and is disposed above the spin base 111 when the inert gas is exhausted. The arm 153 is coupled to the turning drive portion 190 via a swing shaft (not illustrated). The turning drive portion 190 is electrically connected to the control unit 300, and pivots the arm 153 in response to an operation command from the control unit 300. As the arm 153 pivots, the nozzle 152 also moves.

### <Etching Solution Supply Portion>

An etching liquid supply portion 160 is a means that supplies the etching liquid to the front surface Wf of the substrate W. As illustrated in FIG. 6, the etching liquid supply portion 160 includes an etching liquid storage portion 161, a nozzle 162, and an arm 163.

As illustrated in FIG. 10, the etching liquid storage portion 161 includes at least an etching liquid tank 164, a temperature regulator 165, a liquid feeding pump 166, and a particle filter 167. FIG. 10 is an explanatory diagram showing a schematic configuration of the etching liquid storage portion 161 in the etching liquid supply portion 160.

The etching liquid tank 164 may include a stirring portion (not illustrated) that stirs the etching liquid in the etching liquid tank 164. Examples of the stirring portion include a rotation unit that stirs the etching liquid and a stirring control unit that controls the rotation of the rotation unit. The stirring control unit is electrically connected to the control unit 300, and the rotation unit includes, for example, a propeller-like stirring blade at a lower end of a rotation axis. The control unit 300 issues an operation command to the stirring control unit to rotate the rotation unit, and thus, the etching liquid can be stirred by the stirring blade. As a result, the concentration and temperature of the etching liquid can be made uniform in the etching liquid tank 164.

The etching liquid tank 164 is provided with a mixer 168 capable of mixing a chemical agent and DIW from an external supply source (not illustrated) to prepare the etching liquid at a predetermined concentration. The chemical agent is a solute that functions as an etchant. Examples of the chemical agent include phosphoric acid and hydrogen fluoride mentioned above.

In addition, a discharge pipe 169 for supplying the etching liquid to the nozzle 162 is line-connected to the etching liquid tank 164. In the middle path of the discharge pipe 169, the temperature adjuster 165, the liquid feeding pump 166, and the particle filter 167 are sequentially interposed to be provided from the upstream to the downstream. The temperature adjuster 165 and the liquid feeding pump 166 are electrically connected to the control unit 300. Thus, the temperature of the etching liquid supplied to the nozzle 162 can be controlled according to an operation command of the control unit 300. In addition, when the liquid feeding pump 166 is controlled according to an operation command of the control unit 300, the etching liquid can be pumped to the nozzle 162 via the discharge pipe 169. The particle filter 167 can remove foreign matters such as particles in the etching liquid.

The nozzle 162 is attached to the distal end portion of the arm 163 that is horizontally extended, and is disposed above the spin base 111 when the etching liquid is discharged. The arm 163 is coupled to the turning drive portion 190 via a turning shaft (not illustrated). The turning drive portion 190 is electrically connected to the control unit 300, and rotates the arm 163 according to an operation command from the control unit 300. The nozzle 162 also moves as a result of the rotation of the arm 163.

### <Dispersion Prevention Cup>

The dispersion prevention cup 180 is provided so as to surround the spin base 111. The dispersion prevention cup 180 is connected to a lift drive mechanism (not illustrated) and can be lifted in the up-down direction. When the treating liquid or the like is supplied to the front surface Wf of the substrate W, the dispersion prevention cup 180 is positioned at a predetermined position by the lift drive mechanism, and surrounds the substrate W held by the chuck pins 116 from a side position. Thus, the treating liquid or the like dispersed from the substrate W or the spin base 111 can be collected.

### <Control Unit>

The control unit 300 is electrically connected to each portion of the semiconductor manufacturing apparatus and controls the operation of each portion. The control unit 300 is configured by a computer including an arithmetic processing unit and a storage unit. As the arithmetic processing unit, a CPU that performs various types of arithmetic processing is used. The storage unit includes a ROM that is a read-only memory for storing a substrate treatment program and an etching treatment program, a RAM that is a readable/writable memory for storing various types of information, and a magnetic disk for storing control software, data, and the like. In the magnetic disk, treating conditions including generation (mixing) conditions of the dispersion liquid and the treating liquid, supply conditions of the treating liquid, the removal liquid, the inert gas, and the etching liquid, conditions for applying ultrasonic waves, rinsing conditions, drying conditions, formation conditions of the SAM, etching conditions, and the like are stored in advance. The CPU reads the treating conditions into the RAM, and controls each portion of the semiconductor manufacturing apparatus in accordance with the contents.

### Second Embodiment

A second embodiment of the present invention will be described below.

The present embodiment is different from the first embodiment in that the etching step is performed in a batch type instead of a single wafer type. Such a configuration can also efficiently form a SAM having high layer density, excellent denseness, favorable suppression or reduction of the occurrence of layer defects, and excellent protection performance on the front surface of the substrate in a shorter time than a conventional layer forming method.

### [Substrate Treating Method (Method for Manufacturing Semiconductor Apparatus)]

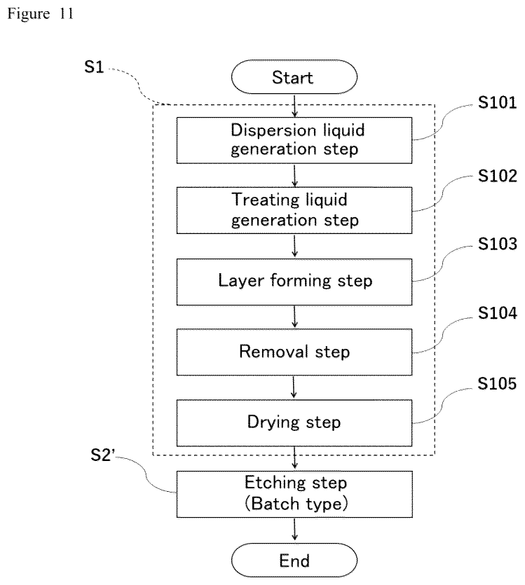

The substrate treating method (method for manufacturing semiconductor apparatus) according to the present embodiment will be described below with reference to FIG. 11. FIG. 11 is a flowchart showing an example of an overall flow of the substrate treating method according to the second embodiment of the present invention. Since the SAM forming step S1 (dispersion liquid generation step S101, treating liquid generation step S102, layer forming step S103, removal step S104, and drying step S105) illustrated in FIG. 11 is similar to that of the first embodiment, the description of these steps will be omitted.

### <Etching Step>

An etching step S2′ is a step of selectively etching the SiN layer 2 which is a layer to be etched by immersing the substrate W after the SAM formation in the etching liquid.

A method of immersing the substrate W in the etching liquid is performed, for example, in a state where the substrate W is in a standing orientation. Here, the “standing orientation” means an orientation in which the front surface of the substrate W is along a substantially vertical direction with respect to the horizontal plane, and includes a case of a vertical orientation. As the etching liquid, a similar etching liquid to the etching liquid described in the first embodiment can be used. An etching temperature (that is, a liquid temperature of the etching liquid) and the etching rate for the layer to be etched can also be appropriately set in consideration of the constituent material of the layer to be etched as in the first embodiment.

### [Substrate Treating Apparatus (Semiconductor Manufacturing Apparatus)]

Next, the semiconductor manufacturing apparatus according to the present embodiment will be described below by exemplifying a case where the substrate treating apparatus is applied to a semiconductor manufacturing apparatus.

The semiconductor manufacturing apparatus according to the present embodiment is different from the substrate treating apparatus according to the first embodiment in that at least a single wafer type substrate treatment unit for forming a SAM and a batch type etching treatment unit for etching a layer to be etched are provided.

### <Substrate Treating Unit>

The substrate treatment unit can have a similar configuration to the semiconductor manufacturing apparatus 100 according to the first embodiment. Therefore, a detailed description thereof will be omitted.

### <Etching Treating Unit>

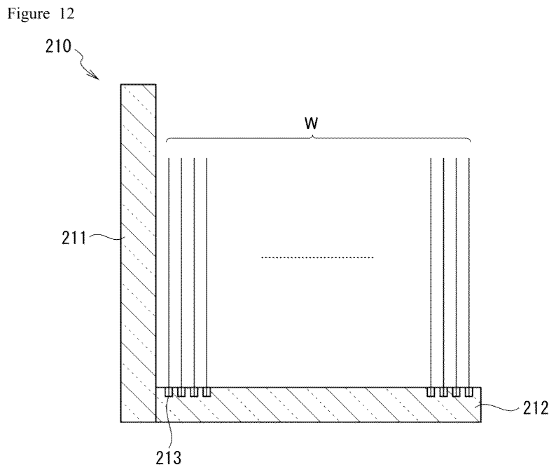

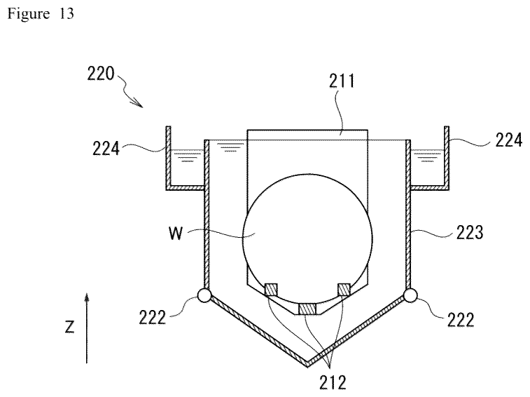

The etching treatment unit according to the present embodiment is a batch type treating unit used to etch a layer to be etched, and performs the etching step S2′ on the substrate W on which the SAM is formed in the substrate treatment unit. As illustrated in FIGS. 12 and 13, the etching treatment unit includes at least a substrate transfer portion (not illustrated), a lifter 210, and a treatment tank 220 that stores an etching liquid. FIG. 12 is a side view showing a schematic configuration of the lifter 210 in the semiconductor manufacturing apparatus according to the present embodiment. FIG. 13 is a sectional view showing a status in which a plurality of substrates W on which a SAM is formed is immersed in the etching liquid according to the present embodiment.

The substrate transfer portion transfers the substrate W on which the SAM is formed in the substrate treatment unit to the etching treatment unit. The substrate transfer portion includes, for example, an articulated robot capable of transferring the substrate W. A transfer arm capable of collectively mounting the substrates W in the horizontal orientation is provided at a distal end of the articulated robot.

As illustrated in FIG. 12, the lifter 210 includes a back plate 211 having a flat plate shape, a plurality of (three) holding rods 212, and a lifting mechanism (not illustrated). The back plate 211 is erected, and at a lower end of the back plate, each of the holding rods 212 extends in one direction so as to be perpendicular to the back plate 211. The holding rod 212 is provided with a plurality of grooves 213 arranged in an extending direction of the holding rod. The plurality of grooves 213 is arranged at equal intervals apart from each other. Furthermore, each groove 213 extends in a direction perpendicular to the extending direction of the holding rod 212, and the plurality of substrates W can be fitted in the standing orientation. In this manner, the holding rod 212 can contact and support a group of the substrates W from below in the standing orientation, and can collectively hold the group of substrates W. The number of the holding rods 212 is not limited as long as the number is plural. The number of grooves 213 provided in the holding rod 212 is not limited, and may be appropriately set in accordance with the number of the substrates W to be held. The lifting mechanism can lift or lower the lifter 210 in a Z direction illustrated in FIG. 13. In this manner, the lifter 210 collectively holding the group of substrates W can be moved to the inside of the treatment tank 220 or can be taken out.

As illustrated in FIG. 13, the treatment tank 220 includes an injection pipe 222 that supplies the etching liquid into the treatment tank 220, an inner tank 223 that stores the etching liquid, and an outer tank 224 provided at a peripheral edge of an upper opening of the inner tank 223. The injection pipe 222 is provided at a bottom of the inner tank 223, and enables upflow supply of the etching liquid to the inner tank 223. The outer tank 224 enables recovery of the etching liquid overflowing from the inner tank 223.

### (Other Matters)

In the above description, the most preferred mode of the present invention has been described. However, the present invention is not limited to the mode. Each configuration in the above embodiments and modifications can be changed, corrected, replaced, added, deleted, and combined within a range not contradictory to each other.

### EXAMPLES

Hereinafter, preferred examples of the present invention will be exemplarily described in detail. However, the materials, blending amounts, conditions, and the like described in the examples are not intended to limit the scope of the present invention only to them unless otherwise limited.

### Example 1

First, in a sealed container in a state of being still, 50 ppm of water was added to toluene as an organic solvent under the conditions of a temperature of 23° C. and normal pressure. Furthermore, an ultrasonic wave was applied to the mixed liquid of toluene and water for 30 minutes in a state of being still. In this manner, a dispersion liquid in which water was uniformly dispersed in toluene as a main solvent was prepared (dispersion liquid generation step). The conditions for applying ultrasonic waves was a frequency of 45 Hz.

Subsequently, octadecyltrichlorosilane as a SAM forming material was added to the dispersion liquid in a state of being still under the conditions of a temperature of 23° C. and normal pressure to prepare a treating liquid (treating liquid generation step). The content (concentration) of octadecyltrichlorosilane was 5% by mass for a total mass of the treating liquid.

On the other hand, separately from the preparation of the treating liquid, a substrate having a SiO₂ film (film thickness: 100 nm) formed on the front surface of the substrate was prepared, and immersed in an aqueous hydrogen fluoride solution for one minute. As the aqueous hydrogen fluoride solution, a solution in which a volume ratio of hydrogen fluoride to DIW was hydrogen fluoride:DIW=1:100 was used.

Next, the substrate pulled up from the aqueous hydrogen fluoride solution was immersed in a treating liquid containing a SAM forming material for five minutes to form a SAM (thickness: about 1 nm) on the front surface of the SiO₂ film of the substrate (layer forming step).

Subsequently, the substrate pulled up from the treating liquid was immersed in toluene as a removal liquid for one minute to remove the unadsorbed SAM forming material remaining on the front surface of the substrate (removal step).

Thereafter, in the substrate pulled up from toluene, nitrogen gas was blown onto the front surface on which the SAM was formed to dry the substrate (drying step). The temperature of the nitrogen gas was set to normal temperature, and the drying time was set to one minute.

Furthermore, the dried substrate was immersed in DIW to remove toluene (rinsing step), and a nitrogen gas was blown onto the front surface on which the SAM was formed to dry the substrate (drying step). The temperature of the nitrogen gas was set to normal temperature. In this manner, a sample according to this example was produced.

Subsequently, the obtained sample was subjected to etching treating. Specifically, the substrate was immersed in an etching liquid to etch a region not protected by the SAM on the front surface of the substrate. As the etching conditions, the immersion time (etching treating time) in the etching liquid was set to 195 seconds so that the etching amount of SiO₂ was about 10 nm. As the etching liquid, an aqueous hydrogen fluoride solution was used, and the volume ratio of hydrogen fluoride to DIW was hydrogen fluoride:DIW=1:100.

Subsequently, the substrate pulled up from the etching liquid was immersed in DIW, and then the substrate was pulled up from DIW (rinsing step with DIW), and nitrogen gas was blown onto the etched front surface to dry the substrate (drying step). The temperature of the nitrogen gas was set to normal temperature.

### Example 2

In this example, the addition amount of water in preparing the dispersion liquid was changed to 100 ppm. Other than the amount, a sample was prepared as in Example 1, and the obtained sample was further subjected to the etching treating.

### Example 3

In this example, the addition amount of water in preparing the dispersion liquid was changed to 200 ppm. Other than the amount, a sample was prepared as in Example 1, and the obtained sample was further subjected to the etching treating.

### Comparative Example 1

In this comparative example, water was not added in preparing the dispersion liquid. Other than the amount, a sample was prepared as in Example 1, and the obtained sample was further subjected to the etching treating.

### Comparative Example 2

In this comparative example, the addition amount of water in preparing the dispersion liquid was changed to 300 ppm. Other than the amount, a sample was prepared as in Example 1, and the obtained sample was further subjected to the etching treating.

### (Evaluation of Denseness of SAM)

For each sample according to Examples 1 to 3 and Comparative Examples 1 and 2, the area of the layer defect of the SAM was calculated, and the denseness of the SAM was evaluated.

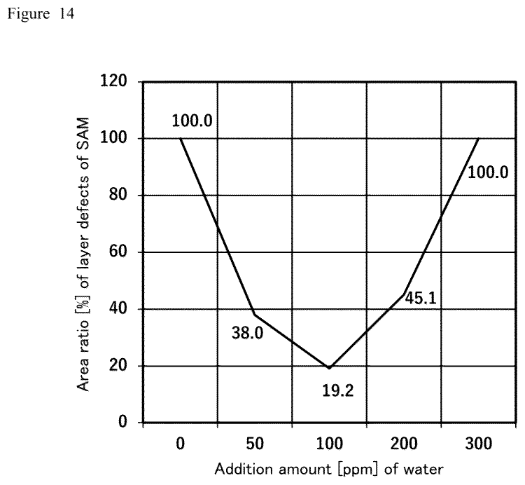

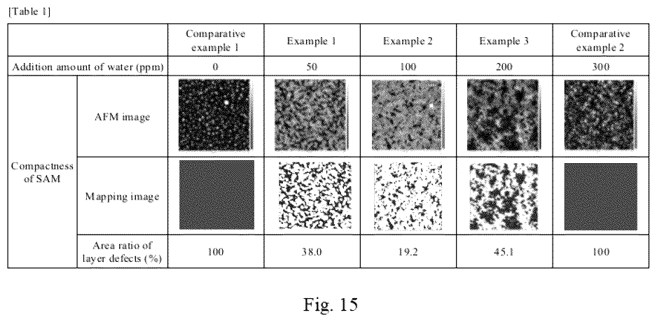

The SAM of each sample was imaged by using an atomic force microscope (AFM) (Trade name: Dimension Icon, manufactured by Bruker Japan K.K.) to obtain an observation image (AFM image) of 500 nm square. Next, each of the obtained observation images was binarized, and then image treating was performed to map the layer defects to identify the site (region) of the layer defects of the SAM. For identification by mapping of the site (region) of the layer defect of the SAM, the image treating was performed so that a defect at a position of less than 1 nm in depth from the front surface of the SAM is mapped, considering that the layer thickness of the SAM is about 1 nm. In this manner, a site (region) having a depth exceeding 1 nm from the front surface of the SAM, specifically, an etched site is mapped as a region of a layer defect of the SAM, and is not included in the area of the defect. Subsequently, the area of the region of the layer defect of the SAM identified by the image treating was calculated, and the ratio of the area to the entire region in the observation image was calculated. The results are shown in Table 1 and FIG. 14. FIG. 14 is a graph showing a relationship between the addition amount (ppm) of water and the area ratio (%) of layer defects of the SAM in each sample of Examples 1 to 3 and Comparative Examples 1 and 2.

As can be seen from Table 1 and FIG. 14, the area ratios of the layer defects of the SAM in Examples 1 to 3 were 38.0%, 19.2%, and 45.1%, respectively. On the other hand, the area ratios of the layer defects of the SAM in Comparative Examples 1 and 2 were both 100%. From the results, it was confirmed that all the SAMs obtained by using the treating liquid of Examples 1 to 3 had good denseness and protection performance.

### DESCRIPTION OF REFERENCE SIGNS

1: SiO₂ layer
2: SiN layer
3: Stack body
4: Memory trench
5: SAM (self-assembled monolayer) molecule
6: Hydroxyl group
9: SAM (self-assembled monolayer)
100: Semiconductor manufacturing apparatus
110: Substrate holding portion
120: Treating liquid supply portion
121: Treating liquid storage portion
124: Organic solvent supply portion
125: Water supply portion
126: SAM (self-assembled monolayer) forming material supply portion
127: Treating liquid tank
129: Inert gas supply portion
130: Ultrasonic wave application portion
140: Removal liquid supply portion
150: Inert gas supply portion
160: Etching liquid supply portion
190: Turning drive portion
210: Lifter
220: Treating tank
300: Control unit
S1: SAM (self-assembled monolayer) forming step
S2, S2′: Etching step
S101: Dispersion liquid generation step
S102: Treating liquid generation step
S103: Layer forming step
S104: Removal step
S105: Drying step
W: Substrate
Wf: Front surface of substrate

1. A substrate treating method for forming a self-assembled monolayer on a surface of a substrate, the substrate treating method comprising:
generating a dispersion liquid in which water is uniformly dispersed in an organic solvent as a main solvent;
adding a material containing a molecule that has a functional group exhibiting hydrolysis reactivity and allows formation of the self-assembled monolayer to the dispersion liquid, and causing a hydrolysis reaction of the water dispersed in the dispersion liquid and the functional group to generate a treating liquid containing the molecule having a hydroxyl group and in which the molecule having a hydroxyl group exists without being aggregated; and
forming the self-assembled monolayer by supplying the treating liquid to the surface of the substrate,
wherein the dispersion liquid is generated by mixing the organic solvent and the water while applying an ultrasonic wave or by mixing the organic solvent and the water and then applying an ultrasonic wave, and
the treating liquid is generated a state where no ultrasonic wave is applied to the dispersion liquid.

2. The substrate treating method according to claim 1, wherein the dispersion liquid is generated with an addition amount of the water in a range of 50 ppm or more and 200 ppm or less in the dispersion liquid.

3. The substrate treating method according to claim 1, wherein in the treating liquid is generated by adding, the material containing the molecule that allows formation of the self-assembled monolayer to the dispersion liquid left still.

4. A method for manufacturing a semiconductor apparatus including a treatment of a substrate in which a stacked body is provided on a surface, the stacked body including layers in which a layer to be protected that is to be protected from etching and a layer to be etched that is to be etched are alternately stacked, the method for manufacturing the semiconductor apparatus comprising:
selectively forming a self-assembled monolayer on at least a surface of the layer to be protected; and
selectively etching the layer to be etched by using the self-assembled monolayer as a protective layer,
wherein forming of the self-assembled monolayer includes
generating a dispersion liquid in which water is uniformly dispersed in an organic solvent as a main solvent,
adding a material containing a molecule that has a functional group exhibiting hydrolysis reactivity and allows formation of the self-assembled monolayer to the dispersion liquid, and causing a hydrolysis reaction of the water dispersed in the dispersion liquid and the functional group to generate a treating liquid containing the molecule having a hydroxyl group and in which the molecule having the hydroxyl group exists without being aggregated, and
forming the self-assembled monolayer by supplying the treating liquid to the surface of the substrate, and
the dispersion liquid is generated by mixing the organic solvent and the water while applying an ultrasonic wave or by mixing the organic solvent and the water and then applying an ultrasonic wave, and
the treating liquid is generated in a state where no ultrasonic wave is applied to the dispersion liquid.

5. The method for manufacturing a semiconductor apparatus according to claim 4, wherein the dispersion liquid is generated with an addition amount of the water in a range of 50 ppm or more and 200 ppm or less in the dispersion liquid.

6. The method for manufacturing a semiconductor apparatus according to claim 4, wherein the treating liquid is generated by adding the material containing the molecule that allows formation of the self-assembled monolayer to the dispersion liquid left still.

7. A substrate treating apparatus that forms a self-assembled monolayer on a surface of a substrate, the substrate treating apparatus comprising:
a treating liquid tank that generates a treating liquid containing a molecule that allows formation of the self-assembled monolayer;
an ultrasonic wave transducer; and
a treating liquid nozzle that supplies the treating liquid generated by the treating liquid tank to the surface of the substrate to form the self-assembled monolayer,
wherein the treating liquid tank generates a dispersion liquid in which water is uniformly dispersed in an organic solvent as a main solvent, further adds a material containing a molecule that has a functional group exhibiting hydrolysis reactivity and allows formation of the self-assembled monolayer to the dispersion liquid, and causes a hydrolysis reaction of the water dispersed in the dispersion liquid and the functional group to generate the treating liquid containing the molecule having a hydroxyl group and in which the molecule having the hydroxyl group exists without being aggregated, and
the ultrasonic wave transducer applies an ultrasonic wave when or after the organic solvent and the water are mixed in the treating liquid tank to generate the dispersion liquid.

8. The substrate treating apparatus according to claim 7, wherein an addition amount of the water when the organic solvent and the water are mixed in the treating liquid tank is in a range of 50 ppm or more and 200 ppm or less.

9. The substrate treating apparatus according to claim 7, wherein the treating liquid tank adds the material containing the molecule that allows formation of the self-assembled monolayer to the dispersion liquid left still.

10. A semiconductor manufacturing apparatus for performing a treatment of a substrate in which a stacked body is provided on a surface, the stacked body including layers in which a layer to be protected that is to be protected from etching and a layer to be etched that is to be etched are alternately stacked,
the semiconductor manufacturing apparatus comprising:
a treating liquid tank that generates a treating liquid containing a molecule that allows formation of a self-assembled monolayer;
an ultrasonic wave transducer;
a treating liquid nozzle that supplies the treating liquid generated by the treating liquid generation portion to the surface of the substrate to form the self-assembled monolayer; and
an etching nozzle that selectively etches and removes the layer to be etched by using the self-assembled monolayer as a protective layer,
wherein the treating liquid tank generates a dispersion liquid in which water is uniformly dispersed in an organic solvent as a main solvent, further adds a material containing a molecule that has a functional group exhibiting hydrolysis reactivity and allows formation of the self-assembled monolayer to the dispersion liquid, and causes a hydrolysis reaction of the water dispersed in the dispersion liquid and a functional group to generate the treating liquid containing the molecule having a hydroxyl group and in which the molecule having the hydroxyl group exists without being aggregated, and
the ultrasonic wave transducer applies an ultrasonic wave when or after the organic solvent and the water are mixed in the treating liquid tank to generate the dispersion liquid.

11. A semiconductor manufacturing apparatus for performing a treatment of a substrate in which a stacked body is provided on a surface, the stacked body including layers in which a layer to be protected that is to be protected from etching and a layer to be etched that is to be etched are alternately stacked,
the semiconductor manufacturing apparatus comprising:
a substrate treatment unit that selectively forms a self-assembled monolayer on at least a surface of the layer to be protected; and
an etching treatment unit that selectively etches and removes the layer to be etched by using the self-assembled monolayer as a protective layer,
wherein the substrate treatment unit includes
a treating liquid tank that generates a treating liquid containing a molecule that allows formation of the self-assembled monolayer,
an ultrasonic wave transducer, and
a treating liquid nozzle that supplies the treating liquid generated by the treating liquid tank to the surface of the substrate to form the self-assembled monolayer,
the treating liquid generation portion generates a dispersion liquid in which water is uniformly dispersed in an organic solvent as a main solvent, further adds a material containing a molecule that has a functional group exhibiting hydrolysis reactivity and allows formation of the self-assembled monolayer to the dispersion liquid, and causes a hydrolysis reaction of the water dispersed in the dispersion liquid and the functional group to generate the treating liquid containing the molecule having a hydroxyl group and in which the molecule having the hydroxyl group exists without being aggregated, and
the ultrasonic wave transducer applies an ultrasonic wave when or after the organic solvent and the water are mixed in the treating liquid tank to generate the dispersion liquid.

12. The semiconductor manufacturing apparatus according to claim 11, wherein an addition amount of the water when the organic solvent and the water are mixed in the treating liquid tank is in a range of 50 ppm or more and 200 ppm or less.

13. The semiconductor manufacturing apparatus according to claim 11, wherein the treating liquid tank adds the material containing the molecule that allows formation of the self-assembled monolayer to the dispersion liquid left still.

14. The semiconductor manufacturing apparatus according to claim 10, wherein the addition amount of the water when the organic solvent and the water are mixed in the treating liquid tank is in a range of 50 ppm or more and 200 ppm or less.

15. The semiconductor manufacturing apparatus according to claim 10, wherein the treating liquid tank adds the material containing the molecule that allows formation of the self-assembled monolayer to the dispersion liquid left still.
